(19) United States
(12) Patent Application Publication
(10) Pub. No.: US 2024/0292130 A1
(43) Pub. Date: Aug. 29, 2024

(54) IMAGING DEVICE AND ELECTRONIC APPARATUS

(71) Applicant: SONY SEMICONDUCTOR SOLUTIONS CORPORATION, KANAGAWA (JP)

(72) Inventor: KOUJI MATSUURA, KANAGAWA (JP)

(21) Appl. No.: 18/292,351

(22) PCT Filed: Mar. 31, 2022
(86) PCT No.: PCT/JP2022/016628

§ 371 Date: Jan. 26, 2024

(30) Foreign Application Priority Data
Aug. 26, 2021 (JP) 2021-138359

(51) Int. Cl. H04N 25/78; H04N 25/77

(52) U.S. Cl. CPC H04N 25/78; H04N 25/77

(57) ABSTRACT

[Problem] To expand the dynamic range, increase the frame rate, and reduce power consumption during photoelectric conversion.

[Solution] An imaging device includes a pixel unit that outputs a photoelectrically converted pixel signal to a signal line, an AD converter that performs AD conversion on the pixel signal on the signal line and determines illuminance based on the pixel signal, and a switching circuit that switches whether to input the pixel signal on the signal line to the AD converter and whether to output the illuminance determination signal determined by the AD converter to the signal line in conjunction with each other. The pixel unit includes a first photoelectric conversion portion, a conversion efficiency adjustment circuit that switches the conversion efficiency when converting the charge photoelectrically converted by the first photoelectric conversion portion into voltage, a first readout circuit that outputs a pixel signal corresponding to the charge photoelectrically converted by the first photoelectric conversion portion to the signal line, and a holding circuit that holds the determination signal.

### TECHNICAL FIELD

The present disclosure relates to an imaging device and an electronic apparatus.

### BACKGROUND ART

A CMOS (Complementary Metal Oxide Semiconductor) image sensor (hereinafter also referred to as CIS) is known in which a comparator compares an analog pixel signal and a linearly changing reference signal and counts the time until the reference signal crosses the pixel signal to thereby AD (Analogue-to-Digital) convert the pixel signal.

There are various types of CIS, and a CIS in which a plurality of photoelectric conversion elements with different light-receiving areas are provided in a pixel and AD conversion is performed by switching the sensitivity and charge-voltage conversion efficiency of the pixel in a plurality of ways to expand the dynamic range during photoelectric conversion has been proposed (see PTL 1).

### CITATION LIST

### Patent Literature

### PTL 1

JP 2017-175345A

### SUMMARY

### Technical Problem

AD conversion is usually performed in units of pixel columns, and pixels arranged in the row (line) direction need to be read out within one horizontal line period. As described above, if each pixel is read out while switching the sensitivity and conversion efficiency, there is a problem that the frame rate cannot be increased because the readout takes time. Furthermore, each time the sensitivity or conversion efficiency is changed, the pixel signal on the vertical signal line must be changed, which increases power consumption.

Therefore, the present disclosure provides an imaging device and an electronic apparatus that can increase the frame rate and reduce power consumption while widening the dynamic range during photoelectric conversion.

### Solution to Problem

In order to solve the above problems, according to the present disclosure, there is provided an imaging device including:
a pixel unit that outputs a photoelectrically converted pixel signal to a signal line;
an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and the conversion efficiency adjustment circuit adjusts the conversion efficiency based on the determination signal held in the holding circuit.

The switching circuit may switch whether to output a pixel signal from the pixel unit to the signal line, whether to connect a current source to the signal line, whether to input the pixel signal on the signal line to the analog-to-digital converter, whether to supply the determination signal of the illuminance from the analog-to-digital converter to the signal line, and whether to input the determination signal on the signal line to the holding circuit in conjunction with each other.

After the holding circuit holds the determination signal, a pixel signal from the pixel unit may be output to the signal line.

The imaging device may further include: a plurality of the pixel units arranged in a first direction and a second direction, wherein the pixel signals output from two or more pixel units arranged in the second direction may be output to a common signal line, and the signal line and the analog-to-digital converter may be arranged for each pixel column made up of two or more pixel units arranged in the second direction.

The pixel unit may include a second photoelectric conversion portion having a smaller light-receiving area than the first photoelectric conversion portion, and the pixel unit may output a plurality of pixel signals with a combination of a plurality of sensitivities and a plurality of conversion efficiencies by controlling the first photoelectric conversion portion, the second photoelectric conversion portion, and the conversion efficiency adjustment circuit.

The pixel unit may include a control signal selection circuit that selects a first control signal for adjusting the conversion efficiency and a second control signal for selecting the first photoelectric conversion portion or the second photoelectric conversion portion based on the determination signal held in the holding circuit, and
the pixel unit may output, to the signal line, the pixel signal which has been photoelectrically converted by the first photoelectric conversion portion or the second photoelectric conversion portion selected based on the second control signal, and of which the conversion efficiency is adjusted based on the first control signal.

The pixel unit may include a second readout circuit that generates a pixel signal corresponding to the charge photoelectrically converted by the second photoelectric conversion portion, and
the control signal selection circuit may select a control signal for the first readout circuit and a control signal for the second readout circuit based on the determination signal held in the holding circuit.

The pixel unit may include a pixel signal selector that selects either a pixel signal corresponding to the charge photoelectrically converted by the first photoelectric conversion portion and a pixel signal corresponding to the charge photoelectrically converted by the second photoelectric conversion portion based on the determination signal held in the holding circuit and selects the selected pixel signal to the signal line.

The pixel unit may include a second readout circuit that generates a pixel signal corresponding to the charge photoelectrically converted by the second photoelectric conversion portion,
the first readout circuit may switch whether to output a pixel signal corresponding to the charge photoelectrically converted by the first photoelectric conversion portion to the signal line based on the determination signal held in the holding circuit, and
the second readout circuit may switch whether to output a pixel signal corresponding to the charge photoelectrically converted by the second photoelectric conversion portion to the signal line based on the determination signal held in the holding circuit.

The analog-to-digital converter may include:
a comparator that compares the pixel signal on the signal line with a reference signal; and
a counter that performs a counting operation until the comparator detects a match between the pixel signal and the reference signal,
the analog-to-digital converter may generate a digital pixel signal corresponding to the pixel signal on the signal line based on a count value of the counter, and the comparator may generate the determination signal of the illuminance by comparing the pixel signal on the signal line with the reference signal.

The comparator may generate the determination signal indicating whether the illuminance at the time of starting imaging is equal to or higher than a predetermined reference level by comparing the pixel signal on the signal line and the reference signal.

The imaging device may further include: a first floating diffusion region that accumulates the charge photoelectrically converted by the first photoelectric conversion portion; and
a second floating diffusion region that accumulates the charge photoelectrically converted by the second photoelectric conversion portion, wherein
the analog-to-digital converter may determine the illuminance based on a comparison result from the comparator comparing the pixel signal corresponding to the charge photoelectrically converted by the second photoelectric conversion portion and accumulated in the second floating diffusion region with the reference signal.

When starting imaging, the comparator may perform a first comparison process of comparing the pixel signal corresponding to a potential of the second floating diffusion region in a state in which the charges in the second floating diffusion region are discharged with the reference signal and then may perform a second comparison process of comparing the pixel signal corresponding to the charge photoelectrically converted by the second photoelectric conversion portion and accumulated in the second floating diffusion region with the reference signal, and the analog-digital converter may determine the illuminance based on the result of the second comparison process.

The comparator may determine whether the illuminance at the time of starting imaging is equal to or higher than the reference level in the second comparison process, and
the pixel unit may output a pixel signal corresponding to the charge photoelectrically converted by the second photoelectric conversion portion to the signal line when the illuminance is equal to or higher than the reference level, and may output a pixel signal corresponding to the charge photoelectrically converted by the first photoelectric conversion portion to the signal line when the illuminance is less than the reference level.

When the illuminance is determined to be equal to or higher than the reference level in the second comparison process, the comparator may perform a third comparison process of comparing the pixel signal corresponding to the charge photoelectrically converted by the second photoelectric conversion portion and accumulated in the second floating diffusion region with the reference signal and then may perform a fourth comparison process of comparing the pixel signal corresponding to the potential of the second floating diffusion region in a state in which the charges in the second floating diffusion region are discharged with the reference signal.

When the illuminance is determined to be less than the reference level in the second comparison process, the comparator may perform a fifth comparison process of comparing the pixel signal corresponding to the potential of the first floating diffusion region in a state where the charges of the first floating diffusion region are discharged with the reference signal, then may perform a sixth comparison process of comparing the pixel signal corresponding to the potential of the first floating diffusion region in a state where a charge-potential conversion efficiency is higher than in the fifth comparison process and the charges of the first floating diffusion region are discharged with the reference signal, then may perform a seventh comparison process of comparing the pixel signal corresponding to the charge photoelectrically converted by the first photoelectric conversion portion with the same charge-potential conversion efficiency as in the sixth comparison process with the reference signal, and then may perform an eighth comparison process of comparing the pixel signal corresponding to the charge photoelectrically converted by the first photoelectric conversion portion with the same charge-potential conversion efficiency as in the fifth comparison process with the reference signal.

According to the present disclosure, there is provided an electronic apparatus including: an imaging device that outputs a digital pixel signal corresponding to an imaged pixel signal; and
a signal processing unit that performs signal processing based on the digital pixel signal, wherein
the imaging device includes:
a pixel unit that outputs a photoelectrically converted pixel signal to a signal line; an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein
the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and
the conversion efficiency adjustment circuit adjusts the conversion efficiency based on the determination signal held in the holding circuit.

### BRIEF DESCRIPTION OF DRAWINGS

FIG. 1 is a block diagram illustrating a schematic configuration of an imaging device according to a first embodiment of the present disclosure.

FIG. 2 is a conceptual diagram illustrating an example of an imaging device in which a semiconductor chip of a pixel array unit and a semiconductor chip of a processing circuit are stacked.

FIG. 3 is a circuit diagram illustrating the basic configuration of a high-dynamic range pixel.

FIG. 4 is a timing chart at the start of exposure of the pixels in FIG. 3.

FIG. 5 is a timing chart when reading out pixel signals in FIG. 3.

FIG. 6 is a circuit diagram of the main parts of the imaging device according to the first embodiment.

FIG. 7 is a diagram illustrating the relationship between illuminance and the potential level of a vertical signal line.

FIG. 8 is a timing diagram of the imaging device according to the first embodiment.

FIG. 9A is a circuit diagram illustrating a first specific example of the latch illustrated in FIG. 7.

FIG. 9B is a circuit diagram illustrating a second specific example of the latch in FIG. 7.

FIG. 10 is a circuit diagram of main parts of an imaging device according to a second embodiment.

FIG. 11 is a timing diagram of the imaging device in FIG. 10.

FIG. 12 is a circuit diagram of main parts of a first modified example of the imaging device illustrated in FIG. 10.

FIG. 13 is a timing diagram of the imaging device in FIG. 12.

FIG. 14 is a circuit diagram of main parts of a second modified example of the imaging device illustrated in FIG. 10.

FIG. 15 is a timing diagram of the imaging device in FIG. 14.

FIG. 16 is a circuit diagram of main parts of an imaging device according to a third embodiment.

FIG. 17 is a timing diagram of the imaging device in FIG. 16.

FIG. 18 is a circuit diagram of main parts of an imaging device according to a fourth embodiment.

FIG. 19 is a timing diagram of the imaging device in FIG. 18.

FIG. 20 is a circuit diagram of main parts of an imaging device according to a modified example of FIG. 18.

FIG. 21 is a timing diagram of the imaging device in FIG. 20.

FIG. 22 is a planar layout diagram of the light incidence surface side of the imaging device according to the first and second embodiments.

FIG. 23 is a planar layout diagram according to a modified example.

FIG. 24 is a block diagram illustrating an example of an overall configuration of a vehicle control system.

FIG. 25 is an explanatory diagram illustrating an example of positions at which a vehicle exterior information detection unit and an imaging unit are installed.

### DESCRIPTION OF EMBODIMENTS

Hereinafter, embodiments of an imaging device 100 and an electronic apparatus will be described with reference to the drawings. Although the main components of the imaging device 100 and the electronic apparatus will be mainly described below, the imaging device 100 and the electronic apparatus may include components and functions that are not illustrated or explained. The following description does not exclude components or functions that are not illustrated or described.

### First Embodiment

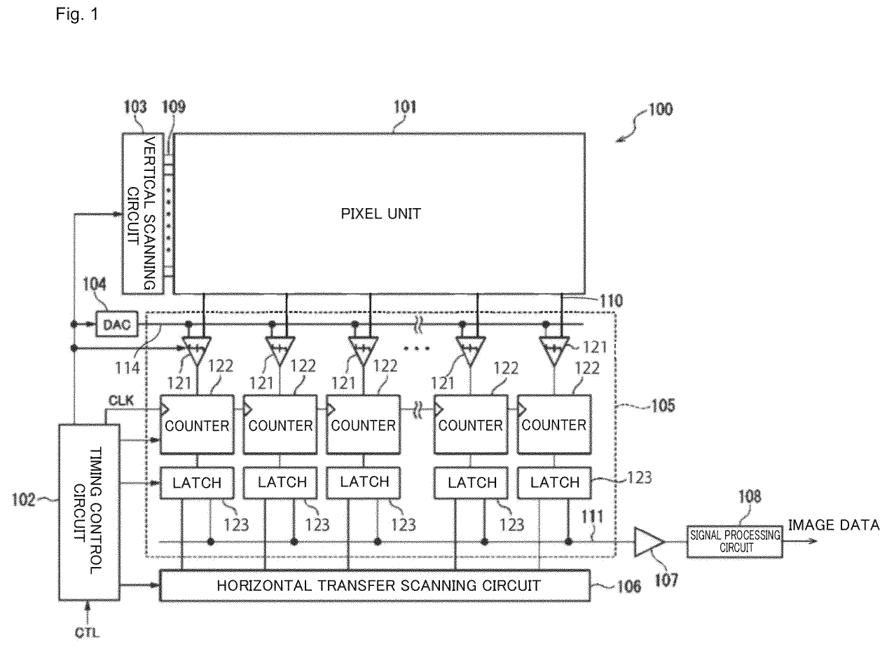

FIG. 1 is a block diagram illustrating a schematic configuration of an imaging device 100 according to a first embodiment of the present disclosure. The imaging device 100 includes a pixel array unit 101, a timing control circuit 102, a vertical scanning circuit 103, a DAC (digital-analog converter) 104, an ADC (analog-digital converter) group 105, a horizontal transfer scanning circuit 106, an amplifier circuit 107, and a signal processing circuit 108.

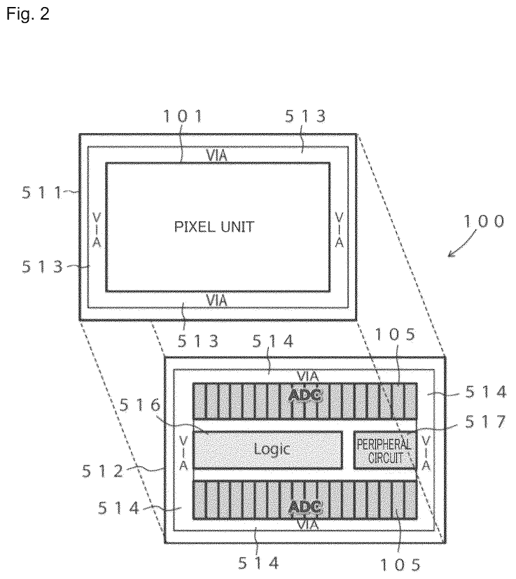

In the pixel array unit 101, unit pixels (hereinafter also simply referred to as pixels) including photoelectric conversion elements that photoelectrically convert incident light into an amount of charge (pixel signal) corresponding to the amount of light are arranged in a matrix. A specific circuit configuration of the unit pixel will be described later with reference to FIG. 2. In addition, in the pixel array unit 101, pixel drive lines 109 are wired for each row along the left-right direction of the figure (pixel arrangement direction/horizontal direction of the pixel rows) with respect to the matrix-like pixel array, and vertical signal lines VSL are wired along the up-down direction of the figure (pixel arrangement direction/vertical direction of pixel columns). One end of the pixel drive line 109 is connected to an output end corresponding to each row of the vertical scanning circuit 103. Note that although FIG. 1 illustrates one pixel drive line 109 for each pixel row, two or more pixel drive lines 109 may be provided for each pixel row.

The timing control circuit 102 includes a timing generator (not illustrated) that generates various timing signals. The timing control circuit 102 controls the vertical scanning circuit 103, the DAC 104, the ADC group 105, the horizontal transfer scanning circuit 106, and the like based on various timing signals generated by the timing generator based on control signals or the like supplied from the outside.

The vertical scanning circuit 103 includes a shift register, an address decoder, and the like. Although illustration of a specific configuration is omitted here, the vertical scanning circuit 103 includes a readout scanning system and a sweeping scanning system.

The readout scanning system sequentially performs a selective scan on a row-by-row basis for unit pixels from which signals are to be read out. On the other hand, the sweep scanning system performs a sweep scan to sweep out (reset) unnecessary charges from the photoelectric conversion element of the unit pixel of a readout row subjected to readout scan by the readout scanning system at a time, a shutter speed ahead of the readout scan. A so-called electronic shutter operation is performed by the sweeping out (resetting) of unnecessary charges by this sweep scanning system. Here, the electronic shutter operation refers to an operation of discarding the photocharges of the photoelectric conversion element and starting new exposure (starting accumulation of photocharges). The signal read out by the readout operation by the readout scanning system corresponds to the amount of light incident after the previous readout operation or electronic shutter operation. The period from the readout timing of the previous readout operation or the sweep timing of the electronic shutter operation to the readout timing of the current readout operation corresponds to the photocharge accumulation time (exposure time) in the unit pixel.

Pixel signals (analog signals) output from each unit pixel in a pixel row selectively scanned by the vertical scanning circuit 103 are supplied to the ADC group 105 via a plurality of vertical signal lines VSL corresponding to each column.

The DAC 104 generates a reference signal RAMP, which is a ramp waveform signal that changes linearly, and supplies it to the ADC group 105. The DAC 104 is commonly connected to a plurality of comparators 121 via a reference signal line 114, and supplies the same reference signal RAMP to the plurality of comparators 121. The reference signal line 114 transmits the reference signal RAMP to the plurality of comparators 121.

The ADC group 105 includes a plurality of comparators 121, a plurality of counters 122, and a plurality of latch circuits 123. The ADC group 105 converts pixel signals (analog signals) from the pixel array unit 101 into digital signals.

The comparator 121, the counter 122, and the latch circuit 123 are provided corresponding to the pixel columns of the pixel array unit 101, respectively, and constitute an ADC 105a. The ADC 105a is provided for each pixel column in the column direction.

The comparator 121 compares the voltage of the signal obtained by adding the pixel signal output from each pixel and the reference signal RAMP via a capacitance with a predetermined reference voltage, and supplies an output signal indicating the comparison result to the counter 122.

The counter 122 counts the time until the voltage magnitude relationship between the pixel signal and the reference signal RAMP is reversed based on the output signal of the comparator 121. In this way, an analog pixel signal is converted into a digital pixel signal represented by a count value. The counter 122 supplies a count value to the latch circuit 123.

The latch circuit 123 holds the count value supplied from the counter 122. Further, the latch circuit 123 performs CDS (Correlated Double Sampling) by taking the difference between the count value of the data signal corresponding to the pixel signal at the signal level and the reset signal count value corresponding to the pixel signal at the reset level.

The horizontal transfer scanning circuit 106 includes a shift register, an address decoder, and the like, and sequentially selectively scans circuit portions corresponding to the pixel columns of the ADC group 105. By this selective scan by the horizontal transfer scanning circuit 106, the digital pixel signals held in the latch circuit 123 are sequentially transferred to the amplifier circuit 107 via a horizontal transfer line 111.

The amplifier circuit 107 amplifies the digital pixel signal supplied from the latch circuit 123 and supplies it to the signal processing circuit 108.

The signal processing circuit 108 performs predetermined signal processing on the digital pixel signal supplied from the amplifier circuit 107 to generate two-dimensional image data. For example, the signal processing circuit 108 corrects vertical line defects and point defects, clamps signals, and performs digital signal processing such as parallel-to-serial conversion, compression, encoding, addition, averaging, and intermittent operation. The signal processing circuit 108 outputs the generated image data to a subsequent device.

Note that the imaging device 100 illustrated in FIG. 1 may be configured as a single semiconductor chip as a whole, or may be configured as a plurality of semiconductor chips. When the imaging device 100 is configured as a plurality of semiconductor chips, the pixel array unit 101 and other processing circuits may be formed as separate semiconductor chips 511 and 512, respectively, and the semiconductor chips 511 and 512 may be stacked.

For example, FIG. 2 is a conceptual diagram illustrating an example of the imaging device 100 in which the semiconductor chip 511 of the pixel array unit 101 and the semiconductor chip 512 of the processing circuit are stacked. As illustrated in FIG. 2, the imaging device 100 is composed of two stacked semiconductor chips 511 and 512. Note that the number of layers of semiconductor chips may be three or more.

The semiconductor chip 511 includes the pixel array unit 101 formed on a semiconductor substrate. The semiconductor chip 512 includes the ADC group 105, a logic circuit 516, and a peripheral circuit 517 formed on another semiconductor substrate. The logic circuit 516 includes the timing control circuit 102, the vertical scanning circuit 103, the DAC 104, the horizontal transfer scanning circuit 106, and the like. The peripheral circuit 517 includes the signal processing circuit 108 and the like.

Each pixel of the pixel array unit 101 of the semiconductor chip 511 and each element of the ADC group 105, the logic circuit 516, and the peripheral circuit 517 in the semiconductor chip 512 may be electrically connected to a through electrode or the like such as a TSV (Through Silicon Via) provided in via regions 513 and 514, for example. The ADC group 105 can transmit and receive signals to and from the pixel array unit 101 via the TSV. Further, both semiconductor chips may be bonded together so that the wiring of the semiconductor chip 511 and the wiring of the semiconductor chip 512 are in contact with each other (Cu—Cu bonding). Furthermore, although not illustrated, at least part of the pixel array unit 101, the ADC group 105, the logic circuit 516, and the peripheral circuit 517 may be configured as one semiconductor chip 511, and the other components may be configured as another semiconductor chip 512.

Each pixel in the pixel unit in FIG. 1 outputs a high dynamic range (hereinafter also referred to as HDR) pixel signal. Before explaining the specific configuration of the pixel according to the first embodiment, the basic configuration of a high-dynamic range pixel will be explained.

### (Basic Configuration of High Dynamic Range Pixels) High Dynamic Range

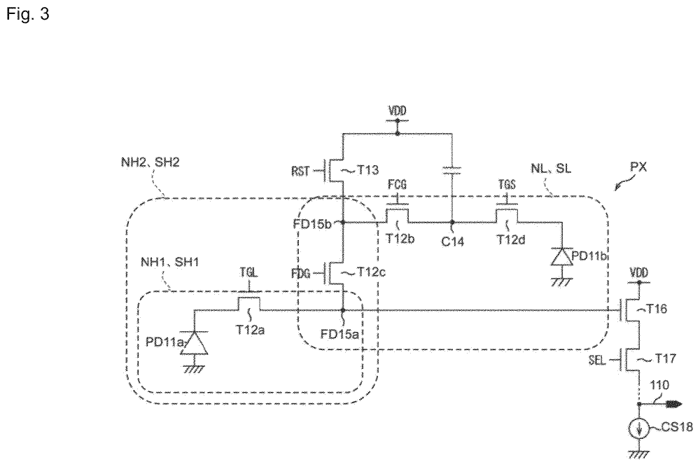

FIG. 3 is a circuit diagram illustrating the basic configuration of a high-dynamic range pixel. The pixel PX in FIG. 3 includes a first photoelectric conversion portion PD11a, a second photoelectric conversion portion PD11b, first to fourth transfer gate portions T12a to T12d, a reset transistor T13, a charge accumulation portion C14, a first floating diffusion region (floating diffusion)) FD15a, a second floating diffusion region (floating diffusion) FD15b, an amplification transistor T16, and a selection transistor T17.

Further, a plurality of pixels PX in FIG. 3 are arranged in the row direction and in the column direction, and the pixel drive line 109 in FIG. 1 is provided for each pixel row arranged in the row direction. Various drive signals TGL, FCG, FDG, TGS, RST, and SEL are supplied from the vertical scanning circuit 103 in FIG. 1 via a plurality of drive lines.

The first photoelectric conversion portion PD11a includes, for example, a PN junction photodiode. The first photoelectric conversion portion PD11a generates and accumulates charges according to the amount of received light. The second photoelectric conversion portion PD11b includes, for example, a PN junction photodiode, like the first photoelectric conversion portion PD11a. The second photoelectric conversion portion PD11b generates and accumulates charges according to the amount of received light.

Comparing the first photoelectric conversion portion PD11a and the second photoelectric conversion portion PD11b, the first photoelectric conversion portion PD11a has a larger light-receiving surface area and higher sensitivity than the second photoelectric conversion portion PD11b.

The first transfer gate portion T12a is connected between the first photoelectric conversion portion PD11a and the first floating diffusion region FD15a. A drive signal TGL is applied to the gate electrode of the first transfer gate portion T12a. When the drive signal TGL becomes active, the first transfer gate portion T12a becomes conductive, and the charges accumulated in the first photoelectric conversion portion PD11a are transferred to the first floating diffusion region FD15a via the first transfer gate portion T12a.

The second transfer gate portion T12b is connected between the charge accumulation portion 104 and the second floating diffusion region FD15b. A drive signal FCG is applied to the gate electrode of the second transfer gate portion T12b. When the drive signal FCG becomes active, the second transfer gate portion T12b becomes conductive, and the potentials of the charge accumulation portion 104 and the second floating diffusion region FD15b are combined.

A conversion efficiency switching transistor T12c is connected between the first floating diffusion region FD15a and the second floating diffusion region FD15b. A drive signal FDG is applied to the gate electrode of the conversion efficiency switching transistor T12c. When the drive signal FDG becomes active, the conversion efficiency switching transistor T12c becomes conductive, and the potentials of the first floating diffusion region FD15a and the second floating diffusion region FD15b are combined.

The fourth transfer gate portion T12d is connected between the second photoelectric conversion portion PD11b and the charge accumulation portion C14. A drive signal TGS is applied to the gate electrode of the fourth transfer gate portion T12d. When the drive signal TGS becomes active, the fourth transfer gate portion T12d becomes conductive, and the charges accumulated in the second photoelectric conversion portion PD11b are transferred to the charge accumulation portion C14 via the fourth transfer gate portion T12d.

In addition, the potential in the lower part of the gate electrode of the fourth transfer gate portion T12d is slightly deep, exceeding the saturation charge amount of the second photoelectric conversion portion PD11b, and an overflow path that transfers the charge overflowing from the second photoelectric conversion portion PD11b to the charge accumulation portion C14 is formed. Note that, hereinafter, the overflow path formed under the gate electrode of the fourth transfer gate portion T12d will be simply referred to as an overflow path of the fourth transfer gate portion T12d.

The reset transistor T13 is connected between a power supply that supplies a power supply voltage VDD (hereinafter, the power supply may also be referred to as VDD) and the second floating diffusion region FD15b. A drive signal RST is applied to the gate electrode of the reset transistor T13. When the drive signal RST becomes active, the reset transistor T13 becomes conductive. As a result, for example, the potential of the region in which the potentials the first floating diffusion region FD15a and the second floating diffusion region FD15b are combined, or the potential of the region in which the potentials of the charge accumulation portion C14, the first floating diffusion region FD15a, and the second floating diffusion region FD15b are combined is reset to the level of the power supply voltage VDD.

The charge accumulation portion C14 is made of, for example, a capacitor, and the opposing electrodes of the charge accumulation portion C14 are connected between the power supplies VDD. The charge accumulation portion C14 accumulates charges transferred from the second photoelectric conversion portion PD11b.

The first floating diffusion region FD15a and the second floating diffusion region FD15b convert the charge of the first or second photoelectric conversion portion PD11a or PD11b into a voltage signal and output the voltage signal. By electrically combining or disconnecting the first floating diffusion region FD15a and the second floating diffusion region FD15b, the capacitance of the entire floating diffusion region of the pixel PX can be switched. By switching the capacitance of the floating diffusion region of the pixel PX, the pixel PX can output pixel signals with a plurality of charge-voltage conversion efficiencies.

The amplification transistor T16 has its gate electrode connected to the first floating diffusion region FD15a and a drain electrode connected to the power supply VDD, and serves as an input portion of a readout circuit (a so-called source follower circuit) that reads out the charge held in the first floating diffusion region FD15a. That is, the amplification transistor T16 has its source electrode connected to the vertical signal line VSL via the selection transistor T17, thereby forming a source follower circuit with a constant current source CS18 connected to one end of the vertical signal line VSL.

The selection transistor T17 is connected between the source electrode of the amplification transistor T16 and the vertical signal line VSL. A drive signal SEL is applied to the gate electrode of the selection transistor T17. When the drive signal SEL becomes active, the selection transistor T17 becomes conductive, and the pixel PX in FIG. 3 enters a selected state. In this way, the pixel signal output from the amplification transistor T16 is output to the vertical signal line VSL via the selection transistor T17.

Note that hereinafter, each drive signal becoming active is also referred to as each drive signal being turned on, and each drive signal becoming inactive is also referred to as each drive signal being turned off. Furthermore, hereinafter, each gate portion or each transistor becoming conductive is also referred to as each gate portion or each transistor being turned on, and each gate portion or each transistor becoming non-conductive is also referred to as each gate portion or each transistor being turned off.

### (Example of Operation at Start of Exposure of Pixel PX in FIG. 3)

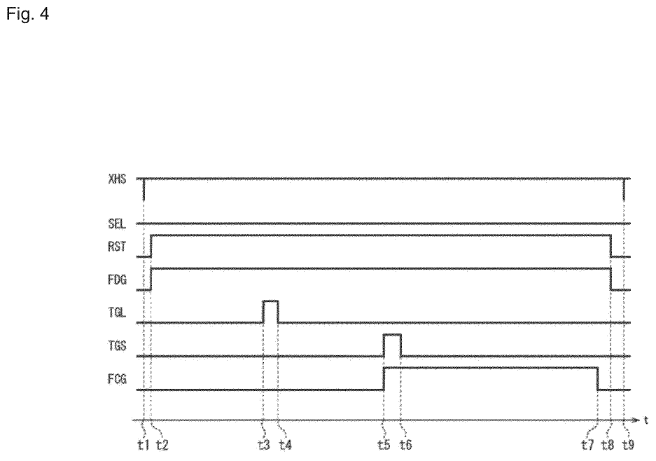

First, an example of the operation of the pixel PX in FIG. 3 at the start of exposure will be described with reference to the timing chart in FIG. 4. This processing is performed, for example, in a predetermined scanning order for each pixel row of the pixel array unit 101 or every plurality of pixel rows. Note that FIG. 4 illustrates a timing chart of the horizontal synchronization signal XHS, drive signals SEL, RST, FDG, TGL, TGS, and FCG.

First, at time t1, the horizontal synchronization signal XHS is input, and the exposure processing of the pixel PX in FIG. 3 is started.

Next, at time t2, the drive signals RST and FDG are turned on, and the reset transistor T13 and the conversion efficiency switching transistor T12c are turned on. As a result, the potentials of the first floating diffusion region FD15a and the second floating diffusion region FD15b are combined, and the potential of the combined region is reset to the level of the power supply voltage VDD.

Next, at time t3, the drive signal TGL is turned on, and the first transfer gate portion T12a is turned on. As a result, the charges accumulated in the first photoelectric conversion portion PD11a are transferred via the first transfer gate portion T12a to the region where the potentials of the first floating diffusion region FD15a and the second floating diffusion region FD15b are combined, and the first photoelectric conversion portion PD11a is reset.

Next, at time t4, the drive signal TGL is turned off, and the first transfer gate portion T12a is turned off. As a result, accumulation of charges in the first photoelectric conversion portion PD11a is started, and an exposure period is started.

Next, at time t5, the drive signals TGS and FCG are turned on, and the fourth transfer gate portion T12d and the second transfer gate portion T12b are turned on. In this way, the potentials of the charge accumulation portion C14, the first floating diffusion region FD15a, and the second floating diffusion region FD15b are combined. Furthermore, the charges accumulated in the second photoelectric conversion portion PD11b are transferred to the combined region via the fourth transfer gate portion T12d, and the second photoelectric conversion portion PD11b and the charge accumulation portion C14 are reset.

Next, at time t6, the drive signal TGS is turned off, and the fourth transfer gate portion T12d is turned off. As a result, accumulation of charges in the second photoelectric conversion portion PD11b is started.

Next, at time t7, the drive signal FCG is turned off, and the second transfer gate portion T12b is turned off. As a result, the charge accumulation portion C14 starts accumulating charges that overflow from the second photoelectric conversion portion PD11b and are transferred via the overflow path of the fourth transfer gate portion T12d.

Next, at time t8, the drive signals RST and FDG are turned off, and the reset transistor T13 and the conversion efficiency switching transistor T12c are turned off.

Then, at time t9, the horizontal synchronization signal XHS is input.

(Example of Operation when Reading Out Pixel PX in FIG. 3)

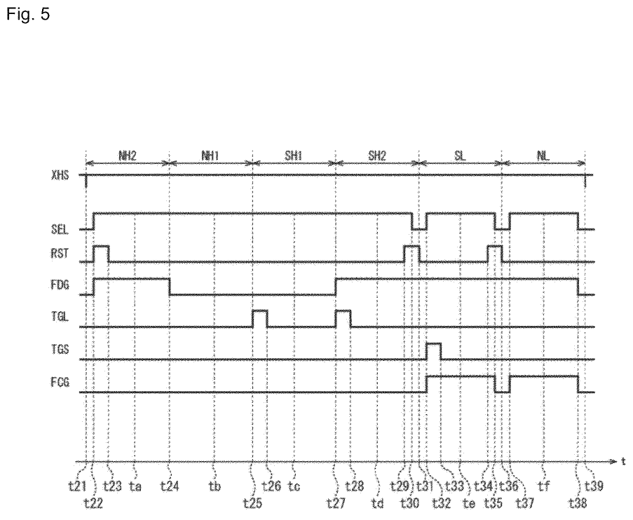

Next, an example of the operation when reading the pixel signal of the pixel PX in FIG. 3 will be described with reference to the timing chart in FIG. 5. This processing is performed, for example, in a predetermined scanning order after a predetermined period of time after the processing in FIG. 4 is performed for each pixel row of the pixel array unit 101 or every plurality of pixel rows. Note that FIG. 5 illustrates a timing chart of the horizontal synchronization signal XHS, drive signals SEL, RST, FDG, TGL, TGS, and FCG.

First, at time t21, the horizontal synchronization signal XHS is input, and a readout period of the pixel PX in FIG. 3 starts.

Next, at time t22, the drive signals SEL, RST, and FDG are turned on, and the selection transistor T17, the reset transistor T13, and the conversion efficiency switching transistor T12c are turned on. In this way, the pixel PX in FIG. 3 enters a selected state. Further, the potentials of the first floating diffusion region FD15a and the second floating diffusion region FD15b are combined, and the potential of the combined region is reset to the level of the power supply voltage VDD.

Next, at time t23, the drive signal RST is turned off, and the reset transistor T13 is turned off.

Next, at time ta between time t23 and time t24, a signal NH2 based on the potentials of the combined first floating diffusion region FD15a and second floating diffusion region FD15b is output to the vertical signal line VSL via the amplification transistor T16 and the selection transistor T17. The signal NH2 is a signal obtained by detecting the reset state of the first photoelectric conversion portion PD11a and the floating diffusion regions FD15a and FD15b in FIG. 3 using the combined region of the first floating diffusion region FD15a and the second floating diffusion region FD15b.

Note that, hereinafter, the signal NH2 will also be referred to as a high-sensitivity reset signal NH2.

Next, at time t24, the drive signal FDG is turned off, and the conversion efficiency switching transistor T12c is turned off. In this way, the potential combining between the first floating diffusion region FD15a and the second floating diffusion region FD15b is eliminated.

Next, at time tb between time t24 and time t25, the signal NH1 based on the potential of the first floating diffusion region FD15a is output to the vertical signal line VSL via the amplification transistor T16 and the selection transistor T17. The signal NH1 is a signal obtained by detecting the reset state of the first photoelectric conversion portion PD11a and the first floating diffusion region FD15a in FIG. 3 using the first floating diffusion region FD15a.

Note that, hereinafter, the signal NH1 will also be referred to as a high-sensitivity reset signal NH1.

Next, at time t25, the drive signal TGL is turned on, and the first transfer gate portion T12a is turned on. In this way, the charges generated and accumulated in the first photoelectric conversion portion PD11a during the exposure period are transferred to the first floating diffusion region FD15a via the first transfer gate portion T12a.

At this time t25, reading of pixel signals is started, and the exposure period ends.

Next, at time t26, the drive signal TGL is turned off, and the first transfer gate portion T12a is turned off. In this way, the transfer of charges from the first photoelectric conversion portion PD11a to the first floating diffusion region FD15a is stopped.

Next, at time tc between time t26 and time t27, the signal SH1 based on the potential of the first floating diffusion region FD15a is output to the vertical signal line VSL via the amplification transistor T16 and the selection transistor T17. The signal SH1 is based on the potential of the first floating diffusion region FD15a when charges generated in the first photoelectric conversion portion PD11a are accumulated in the first floating diffusion region FD15a during the exposure period.

Note that, hereinafter, the signal SH1 will also be referred to as a high-sensitivity data signal SH1.

Next, at time t27, the drive signals FDG and TGL are turned on, and the conversion efficiency switching transistor T12c and the first transfer gate portion T12a are turned on. As a result, the potentials of the first floating diffusion region FD15a and the second floating diffusion region FD15b are combined, and the charge remaining in the first photoelectric conversion portion PD11a without being completely transferred between time t25 and time t26 is transferred to the combined region via the first transfer gate portion T12a. Note that when reading the high-sensitivity data signal SH1, since the capacitance for converting charge to voltage is small relative to the amount of charge to be handled, even if the charge remains in the first photoelectric conversion portion PD11a, it does not pose a problem. The charge remaining in the first photoelectric conversion portion PD11a only needs to be transferred when reading the high-sensitivity data signal SH2, and the charge in the first photoelectric conversion portion PD11a will not be damaged.

Next, at time t28, the drive signal TGL is turned off, and the first transfer gate portion T12a is turned off. In this way, the transfer of charges from the first photoelectric conversion portion PD11a to the region where the potentials of the first floating diffusion region FD15a and the second floating diffusion region FD15b are combined is stopped.

Next, at time td between time t28 and time t29, a signal SH2 based on the potential of the region in which the potentials of the first floating diffusion region FD15a and the second floating diffusion region FD15b are combined is output to the vertical signal line VSL via the amplification transistor T16 and the selection transistor T17. The signal SH2 is based on the potential of the combined region of the first floating diffusion region FD15a and the second floating diffusion region FD15b when the charges generated in the first photoelectric conversion portion PD11a during the exposure period are accumulated in the combined region of the first floating diffusion region FD15a and the second floating diffusion region FD15b. Therefore, the capacitance for converting charge to voltage when reading the signal SH2 is the combined capacitance of the first floating diffusion region FD15a and the second floating diffusion region FD15b, which is larger than that when reading the high-sensitivity data signal SH1 at time tc.

Note that, hereinafter, the signal SH2 will also be referred to as a high-sensitivity data signal SH2.

Next, at time t29, the drive signal RST is turned on and the reset transistor T13 is turned on. As a result, the potential of the region where the potentials of the first floating diffusion region FD15a and the second floating diffusion region FD15b are combined is reset to the level of the power supply voltage VDD.

Next, at time t30, the drive signal SEL is turned off, and the selection transistor T17 is turned off. In this way, the pixel PX in FIG. 3 enters a non-selected state.

Next, at time t31, the drive signal RST is turned off, and the reset transistor T13 is turned off.

Next, at time t32, the drive signals SEL, TGS, and FCG are turned on, and the selection transistor T17, the fourth transfer gate portion T12d, and the second transfer gate portion T12b are turned on. In this way, the pixel PX in FIG. 3 enters a selected state. Further, the potentials of the charge accumulation portion C14, the first floating diffusion region FD15a, and the second floating diffusion region FD15b are combined, and the charges accumulated in the second photoelectric conversion portion PD11b are transferred to the combined region. In this way, the charges accumulated in the second photoelectric conversion portion PD11b and the charge accumulation portion C14 during the exposure period are accumulated in the combined region.

Next, at time t33, the drive signal TGS is turned off, and the fourth transfer gate portion T12d is turned off. In this way, the transfer of charges from the second photoelectric conversion portion PD11b is stopped.

Next, at time te between time t33 and time t34, the signal SL based on the potential of the combined region of the charge accumulation portion C14, the first floating diffusion region FD15a, and the second floating diffusion region FD15b is output to the vertical signal line VSL via the amplification transistor T16 and the selection transistor T17. The signal SL is based on the potential of the combined region of the charge accumulation portion C14, the first floating diffusion region FD15a, and the second floating diffusion region FD15b when the charges generated by the second photoelectric conversion portion PD11b and accumulated in the second photoelectric conversion portion PD11b and the charge accumulation portion C14 are accumulated in the combined region. Therefore, the capacitance for converting charge to voltage when reading the signal SL is the combined capacitance of the charge accumulation portion C14, the first floating diffusion region FD15a, and the second floating diffusion region FD15b. This capacitance is larger than that when reading the high-sensitivity data signal SH1 at time tc and when reading the high-sensitivity data signal SH2 at time td.

Note that, hereinafter, the signal SL will also be referred to as a low-sensitivity data signal SL.

Next, at time t34, the drive signal RST is turned on and the reset transistor T13 is turned on. As a result, the combined region of the charge accumulation portion C14, the first floating diffusion region FD15a, and the second floating diffusion region FD15b is reset.

Next, at time t35, the drive signals SEL and FCG are turned off, and the selection transistor T17 and second transfer gate portion T12b are turned off. In this way, the pixel PX in FIG. 3 enters a non-selected state. Further, the potential of the charge accumulation portion C14 is separated from the potentials of the first floating diffusion region FD15a and the second floating diffusion region FD15b.

Next, at time t36, the drive signal RST is turned off, and the reset transistor T13 is turned off.

Next, at time t37, the drive signals SEL and FCG are turned on, and the selection transistor T17 and second transfer gate portion T12b are turned on. In this way, the pixel PX in FIG. 3 enters a selected state. Furthermore, the potential of the charge accumulation portion C14 is combined with the potentials of the first floating diffusion region FD15a and the second floating diffusion region FD15b.

Next, at time tf between time t37 and time t38, the signal NL based on the potential of the combined region of the charge accumulation portion C14, the first floating diffusion region FD15a, and the second floating diffusion region FD15b is output to the vertical signal line VSL via the amplification transistor T16 and the selection transistor T17. This signal NL is based on the potential in the reset state of the combined region of the charge accumulation portion C14, the first floating diffusion region FD15a, and the second floating diffusion region FD15b.

Note that, hereinafter, the signal NL will also be referred to as a low-sensitivity reset signal NL.

Next, at time t38, the drive signals SEL, FDG, and FCG are turned off, and the selection transistor T17, conversion efficiency switching transistor T12c, and second transfer gate portion T12b are turned off. In this way, the pixel PX in FIG. 3 enters a non-selected state. Further, the potential combining between the charge accumulation portion C14, the first floating diffusion region FD15a, and the second floating diffusion region FD15b is eliminated.

Next, at time t39, the horizontal synchronization signal XHS is input, and the period for reading out the pixel signal of the pixel PX in FIG. 3 ends.

The ADC group 105 AD-converts the pixel signal from the high dynamic range pixel PX illustrated in FIG. 3. In this case, when reading one pixel signal, the ADC group 105 sequentially AD-converts the high-sensitivity reset signal NH2, the high-sensitivity reset signals NH1 and NL, the high-sensitivity data signals SH1 and SH2, the low-sensitivity data signal SL, and the low-sensitivity reset signal NL.

These AD conversions must be performed within one horizontal line period, which may impede speeding up the frame rate. Furthermore, since the potential of the vertical signal line that transfers pixel signals changes frequently, this can be a factor that increases power consumption.

Therefore, in the imaging device 100 according to the first embodiment and the second embodiment described below, even if the sensitivity and conversion efficiency are switched in a plurality of ways, the increase in frame rate is not hindered, and the power consumption is also reduced.

### (Configuration of Main Parts of Imaging Device 100)

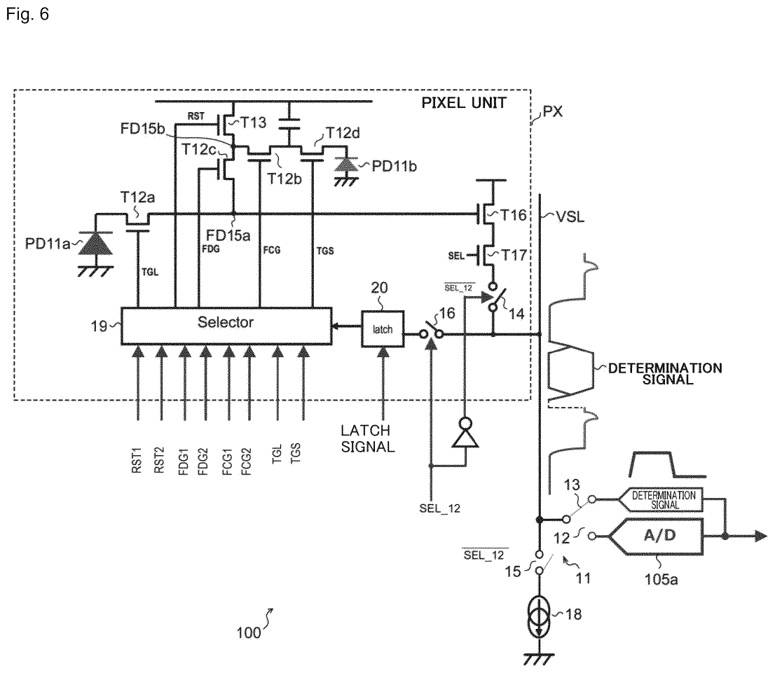

FIG. 6 is a circuit diagram of the main parts of the imaging device 100 according to the first embodiment. Although only one pixel unit PX is illustrated in FIG. 6, in reality, a plurality of pixel units PX are arranged in the row and column directions to constitute the pixel array unit 101 in FIG. 1. Note that in this specification, the pixel unit PX may be abbreviated as pixel PX.

As illustrated in FIG. 6, a vertical signal line VSL is connected to the pixel unit PX. The vertical signal line VSL is provided for each pixel column arranged in the column direction. The vertical signal line VSL is connected to the ADC 105a via the switching circuit 11. More specifically, the switching circuit 11 includes a first switching circuit 12 that switches whether to input a pixel signal on the vertical signal line VSL to the ADC 105a, and a second switching circuit 13 that switches whether to output an illuminance determination signal from the ADC 105a to the vertical signal line VSL. The first switching circuit 12 and the second switching circuit 13 perform switching operations in conjunction with each other.

The illuminance determination signal is a signal that includes the determination result of the ADC 105a determining whether the illuminance is equal to or higher than a predetermined reference level at the start of imaging. The determination signal has a high level or a low level and indicates whether the illuminance is equal to or higher than the reference level. For example, if the determination signal is at a high level, the illuminance may be equal to or higher than the reference level, and if the determination signal is at a low level, the illuminance may be less than the reference level, or the relationship between the high level and the low level may be reversed.

In the present embodiment, the determination signal from the ADC 105a is transmitted to the pixel unit PX via the vertical signal line VSL. Therefore, it is necessary to prevent the pixel signal output from the pixel unit PX to the vertical signal line VSL and the determination signal from colliding on the vertical signal line VSL. Therefore, the pixel unit PX is provided with a third switching circuit 14 that switches whether to output the pixel signal to the vertical signal line VSL.

When outputting a pixel signal from the pixel unit PX to the vertical signal line VSL, a current source 18 is generally connected to the vertical signal line VSL. On the other hand, when supplying the determination signal from the ADC 105a to the pixel unit PX via the vertical signal line VSL, it is not desirable to connect the current source 18 to the vertical signal line VSL. Therefore, a fourth switching circuit 15 is provided to switch whether to connect the current source 18 to the vertical signal line VSL.

The first switching circuit 12, the second switching circuit 13, the third switching circuit 14, and the fourth switching circuit 15 perform switching operations in conjunction with each other. For example, when inputting a pixel signal from the pixel unit PX to the ADC 105a via the vertical signal line VSL, the first switching circuit 12 is turned on, the second switching circuit 13 is turned off, the third switching circuit 14 is turned on, and the fourth switching circuit 15 is turned on. In this way, with the current source 18 connected to the vertical signal line VSL, a pixel signal from the pixel unit PX is input to the ADC 105a through the vertical signal line VSL. In this state, the determination signal is not output to the vertical signal line VSL.

On the other hand, when it is desired to supply the illuminance determination signal determined by the ADC 105a to the pixel unit PX, the first switching circuit 12 is turned off, the second switching circuit 13 is turned on, the third switching circuit 14 is turned off, and the fourth switching circuit 15 is turned off. As a result, only the determination signal is supplied to the vertical signal line VSL, and the pixel signal and the current source 18 are cut off from the vertical signal line VSL.

Note that the settling time of the vertical signal line VSL may be shortened by replacing the current source 18 with a VSL boost circuit including a plurality of MOS transistors and a constant current source.

The pixel unit PX includes the first photoelectric conversion portion PD11a, the second photoelectric conversion portion PD11b, the reset transistor T13, the conversion efficiency switching transistor T12c, the transfer transistors T12a, T12b, T12d, the amplification transistor T16, the selection transistor T17, the control signal selection circuit (selector) 19, the latch 20, the third switching circuit 14, and the fifth switching circuit 16. Only one of the first photoelectric conversion portion PD11a and the second photoelectric conversion portion PD11b may be arranged in the pixel unit PX. For example, even if the second photoelectric conversion portion PD11b is arranged in the pixel unit PX and the first photoelectric conversion portion PD11a is not arranged, the switching circuit 11 can switch whether to input the pixel signal on the signal line to the ADC 105a and whether to output the illuminance determination signal determined by the ADC 105a to the signal line in conjunction with each other.

The fifth switching circuit 16 switches whether to input the determination signal supplied from the ADC 105a via the vertical signal line VSL to the latch 20. The fifth switching circuit 16 operates in conjunction with the first to fourth switching circuits 12 to 15 described above. In particular, the fifth switching circuit 16 is turned on or off in opposition to the third switching circuit 14. That is, the fifth switching circuit 16 is turned off when the third switching circuit 14 is turned on, and the third switching circuit 14 is turned off when the fifth switching circuit 16 is turned on.

The latch 20 holds the determination signal transmitted from the ADC 105a via the vertical signal line VSL when the fifth switching circuit 16 is turned on. The latch 20 holds the determination signal in synchronization with a latch signal. Since the period during which the determination signal is transmitted via the vertical signal line VSL is limited, by holding the determination signal in the latch 20, even if the determination signal is no longer transmitted via the vertical signal line VSL, the pixel unit PX can output a pixel signal corresponding to the determination signal held in the latch 20 to the vertical signal line VSL.

In this way, the latch 20 is necessary because the determination signal from the ADC 105a is only temporarily transmitted to the vertical signal line VSL.

Based on the determination signal held in the latch 20, the control signal selection circuit 19 selects a signal to be supplied to each gate of the reset transistor T13, the conversion efficiency switching transistor T12c, and the transfer transistors T12a, T12b, and T12d from among the control signals RST1, RST2, FDG1, FDG2, FCG1, FCG2, TGL, and TGS input from the outside.

The determination signal held in the latch 20 is a signal indicating whether the illuminance is equal to or higher than a predetermined reference level. When the illuminance is equal to or higher than the reference level, the control signal selection circuit 19 supplies the control signal RST2 to the gate of the reset transistor T13, supplies the control signal FDG2 to the gate of the conversion efficiency switching transistor T12c, supplies the control signal FCG2 to the gate of the transfer transistor T12b, and supplies the control signal TGS to the gate of the transfer transistor T12d.

On the other hand, when the illuminance is less than the reference level, the control signal selection circuit 19 supplies the control signal TGL to the gate of the transfer transistor T12a, supplies the control signal RST1 to the gate of the reset transistor T13, supplies the control signal FDG1 to the gate of the conversion efficiency switching transistor T12c, and supplies the control signal FCG2 to the gate of the transfer transistor T12b.

In this specification, a circuit (the transfer transistor T12a, the amplification transistor T16, and the selection transistor T17) that generates a pixel signal corresponding to the charge photoelectrically converted by the first photoelectric conversion portion PD11a is referred to as a first readout circuit. Further, a circuit (the transfer transistors T12d and T12b, the conversion efficiency switching transistor T12c, the amplification transistor T16, and the selection transistor T17) that generates a pixel signal corresponding to the charge photoelectrically converted by the second photoelectric conversion portion PD11b is referred to as a second readout circuit.

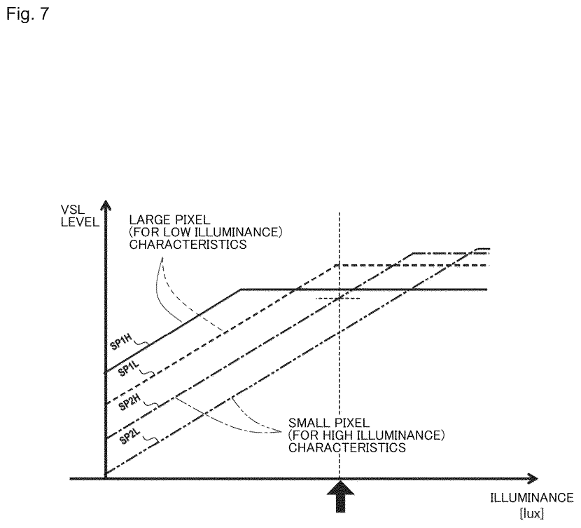

FIG. 7 is a diagram illustrating the relationship between illuminance and the potential level of the vertical signal line VSL. FIG. 7 illustrates a case where photoelectric conversion and AD conversion are performed with high sensitivity and high conversion efficiency (hereinafter sometimes referred to as SP1H), high sensitivity and low conversion efficiency (hereinafter sometimes referred to as SP1L), low sensitivity and no-capacitance (hereinafter referred to as SP2H), and low sensitivity and with-capacitance (hereinafter referred to as SP2L). As illustrated in the figure, in SP1H and SP1L using the first photoelectric conversion portion PD11a having a large light-receiving area, the potential of the vertical signal line VSL is saturated even if the illuminance is not so high. On the other hand, in SP2H and SP2L using the second photoelectric conversion portion PD11b with a small light-receiving area, the potential of the vertical signal line VSL does not saturate even if the illuminance is high.

As can be seen from FIG. 7, by using the second photoelectric conversion portion PD11b with a small light-receiving area, there is no fear that the potential will be saturated, and the illuminance can be determined with higher accuracy. Therefore, in the present embodiment, when starting imaging of each pixel PX, it is determined whether the illuminance is equal to or higher than the reference level using the second photoelectric conversion portion PD11b. If the illuminance is equal to or higher than the reference level, the second photoelectric conversion portion PD11b is used to perform AD conversion a plurality of times with low sensitivity. If the illuminance is less than the reference level, the first photoelectric conversion portion PD11a is used to perform AD conversion a plurality of times while switching the conversion efficiency with high sensitivity.

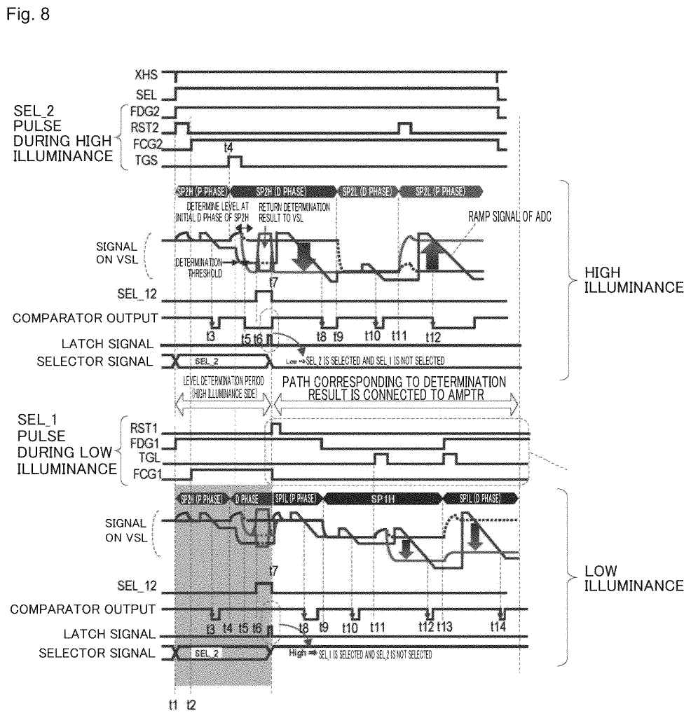

FIG. 8 is a timing diagram of the imaging device 100 according to the first embodiment. In the present embodiment, at the start of imaging, a pixel signal corresponding to the charge photoelectrically converted by the second photoelectric conversion portion PD11b is input to the ADC 105a, and the comparator 121 in the ADC 105a compares the pixel signal with a reference signal to determine whether the illuminance is equal to or higher than a predetermined reference level. When the illuminance is equal to or higher than the reference level (hereinafter referred to as high illuminance), AD conversions in SP2H (reset period), SP2H (data acquisition period), SP2L (data acquisition period), and SP2L (reset period) are performed sequentially within one horizontal line period. In addition, when the illuminance is less than the reference level (hereinafter referred to as low illuminance), AD conversions in SP1L (reset period), SP1H (reset period, data acquisition period), and SP1L (data acquisition period) are performed sequentially within one horizontal line period. The upper half of FIG. 8 illustrates a timing diagram when the illuminance is determined to be high, and the lower half illustrates a timing diagram when the illuminance is determined to be low. In the drawings attached to this specification, SP2H (reset period) is denoted as SP2H (P phase), SP2H (data acquisition period) is denoted as SP2H (D phase), SP2L (data acquisition period) is denoted as SP2L (D phase), and SP2L (reset period) is denoted as SP2L (P phase).

In this specification, SP2H (reset period) is referred to as the first comparison processing, SP2H (data acquisition period) is referred to as the second comparison processing, SP2L (data acquisition period) is referred to as the third comparison processing, SP2L (reset period) is referred to as the fourth comparison processing, SP1L (reset period) is referred to as the fifth comparison processing, SP1H (reset period) is referred to as the sixth comparison processing, SP1H (data acquisition period) is referred to as the seventh comparison processing, and SP1L (data acquisition period) is referred to as the eighth comparison processing.

First, at time t1, the reset transistor T13 is turned on, and the charges in the second floating diffusion region FD15b are discharged to the power supply node. After that, the second photoelectric conversion portion PD11b starts photoelectric conversion (exposure), but since the transfer transistor T12d is still turned off, the second floating diffusion region FD15b maintains the initialization potential. A pixel signal corresponding to this potential is output to the vertical signal line VSL. Therefore, the comparator 121 in the ADC 105a compares the pixel signal corresponding to the initialization potential of the second floating diffusion region FD15b with the reference signal. At time t3, when the pixel signal crosses the reference signal, the output signal of the comparator 121 becomes low. The counter 122 counts the time until the output signal of the comparator 121 becomes low. This count value represents the SP2H reset level.

Thereafter, when the transfer transistor T12d is turned on at time t4, the charge photoelectrically converted by the second photoelectric conversion portion PD11b moves to the second floating diffusion region FD15d via the transfer transistor T12d, and the pixel signal in the data acquisition period is input to the ADC 105a via the vertical signal line VSL.

At time t5, when the pixel signal corresponding to the SP2H data acquisition period crosses the reference signal, the output of the comparator 121 in the ADC 105a becomes low. At this point, the ADC 105a determines whether the illuminance is equal to or higher than the reference level, and outputs a determination signal to the vertical signal line VSL via the second switching circuit 13. The output of the comparator 121 becomes low at time t5 when the illuminance is equal to or higher than the reference level.

First, the operation of the imaging device 100 when the illuminance is determined to be equal to or higher than the reference level will be described below. In this case, the imaging device 100 operates according to the timing illustrated in the upper half of FIG. 8. If the illuminance is determined to be equal to or higher than the reference level, the second photoelectric conversion portion PD11b with a small light-receiving area is continuously used, and the first photoelectric conversion portion PD11a with a large light-receiving area is not used.

When it is determined that the illuminance is equal to or higher than the reference level, a determination signal indicating this is output to the vertical signal line VSL. The determination signal is output to the vertical signal line VSL only during the period from time t6 to t7, and the potential of the vertical signal line VSL becomes temporarily high.

When the ADC 105a outputs a determination signal to the vertical signal line VSL, the first switching circuit 12 is turned off, the second switching circuit 13 is turned on, the third switching circuit 14 is turned off, the fourth switching circuit 15 is turned off, and the fifth switching circuit 16 is turned on. In this way, the determination signal from the ADC 105a is input to the latch 20 in the pixel unit PX via the vertical signal line VSL. The latch 20 holds the determination signal at the timing when the latch signal is input. The control signal selection circuit 19 in the pixel unit PX selects each control signal based on the held determination signal. Specifically, the control signal selection circuit 19 supplies the control signal RST2 to the gate of the reset transistor T13, supplies the control signal FDG2 to the gate of the conversion efficiency switching transistor T12c, supplies the control signal FCG2 to the gate of the transfer transistor T12b, and supplies the control signal TGS to the gate of the transfer transistor T12d.

After time t7, the first switching circuit 12 is turned on, the second switching circuit 13 is turned off, the third switching circuit 14 is turned on, the fourth switching circuit 15 is turned on, and the fifth switching circuit 16 is turned off. When the pixel signal crosses the reference signal at time t8, the output of the comparator 121 transitions to a low level. The counter 122 counts the time until the pixel signal crosses the reference signal. This count value represents the SP2H data (pixel signal) level.

After time t9, SP2L data (pixel signal) is generated. At time t10, when the pixel signal crosses the reference signal, the output of the comparator 121 transitions to a low level. The counter 122 counts the time until the pixel signal crosses the reference signal. This count value represents the SP2L data (pixel signal) level.

Thereafter, at time t11, the control signal RST2 becomes high, the control signal RST2 is input to the gate of the reset transistor T13 via the control signal selection circuit 19, and the reset transistor T13 is turned on. As a result, the charges in the first floating diffusion region FD15a and the second floating diffusion region FD15b are discharged. Therefore, the potential of the first floating diffusion region FD15a rises rapidly, and the signal level of the pixel signal on the vertical signal line VSL also rises rapidly. Thereafter, when the pixel signal crosses the reference signal at time t12, the output of the comparator 121 transitions to a low level. The counter 122 counts the time until the pixel signal crosses the reference signal. This count value represents the SP2L reset level.

On the other hand, if the illuminance is determined to be less than the reference level at time t5, the imaging device 100 operates according to the timing illustrated in the lower half of FIG. 8. In this case, the control signal selection circuit 19 switches each control signal based on the determination signal held in the latch 20. When the illuminance is less than the reference level, the pixel unit PX generates a pixel signal using the first photoelectric conversion portion PD11a having a large light-receiving area, and the second photoelectric conversion portion PD11b is not used.

If it is determined that the illuminance is less than the reference level, the determination signal is output only during the period from time t6 to t7, and the potential of the vertical signal line VSL transitions to, for example, a low level. The determination signal from the ADC 105a is input to the latch 20 in the pixel unit PX via the vertical signal line VSL. The latch 20 holds the determination signal in synchronization with the timing at which the latch signal is input. The control signal selection circuit 19 in the pixel unit PX selects each control signal based on the held determination signal. Specifically, the control signal selection circuit 19 supplies the control signal TGL to the gate of the transfer transistor T12a, supplies the control signal RST1 to the gate of the reset transistor T13, supplies the control signal FDG1 to the gate of the conversion efficiency switching transistor T12c, and supplies the control signal FCG2 to the gate of the transfer transistor T12b.

At time t7, when the control signal RST1 becomes high, the reset transistor T13 is turned on, and the charges in the first floating diffusion region FD15a and the second floating diffusion region FD15b are discharged. As a result, the potentials of the first floating diffusion region FD15a and the second floating diffusion region FD15b are initialized, and the pixel signal on the vertical signal line VSL also becomes the reset potential. Thereafter, when the pixel signal crosses the reference signal at time t8, the output signal of the comparator 121 transitions to a low level. The counter 122 counts the time until the pixel signal crosses the reference signal. This count value represents the SP1L reset level.

After that, at time t9, the control signal FDG1 transitions to a low level, and the conversion efficiency switching transistor T12c is turned off. As a result, after time t9, the first floating diffusion region FD15a is separated from the second floating diffusion region FD15b, and the charge-voltage conversion efficiency increases. Thereafter, at time t10, when the pixel signal crosses the reference signal, the output signal of the comparator 121 transitions to a low level. The counter 122 counts the time until the pixel signal crosses the reference signal. This count value represents the SP1H reset level.

At time t11, the control signal TGL becomes high, the transfer transistor T12a is turned on, and the charge photoelectrically converted by the first photoelectric conversion portion PD11a, which has a large light-receiving area, is transferred to the first floating diffusion region FD15a via the transfer transistor T12a. Thereafter, at time t12, when the pixel signal crosses the reference signal, the output signal of the comparator 121 transitions to a low level. The counter 122 counts the time until the pixel signal crosses the reference signal. This count value represents the SP1H data (pixel signal) level.

After that, at time t13, the control signal FDG1 transitions to a high level, and the conversion efficiency switching transistor T12c is turned on. As a result, after time t13, the first floating diffusion region FD15a and the second floating diffusion region FD15b are combined, and the charge-voltage conversion efficiency becomes low. Further, at time t13, the transfer transistor T12a is turned on, and the charge photoelectrically converted by the first photoelectric conversion portion PD11a is transferred to the first floating diffusion region FD15a via the transfer transistor T12a. Thereafter, when the pixel signal crosses the reference signal at time t14, the output signal of the comparator 121 transitions to a low level. The counter 122 counts the time until the pixel signal crosses the reference signal. This count value represents the SP1L data (pixel signal) level.

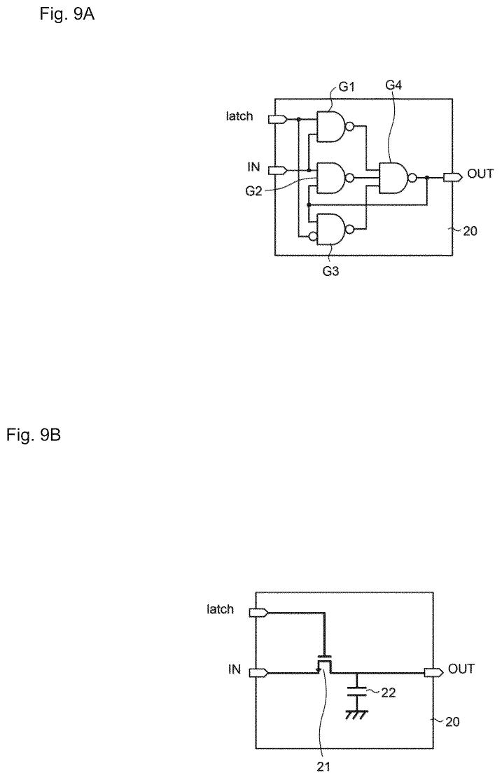

Various configurations can be considered as the internal configuration of the latch 20 in FIG. 7, and a typical internal configuration will be described below. FIG. 9A is a circuit diagram illustrating a first specific example of the latch 20 of FIG. 7. The latch 20 in FIG. 9A is composed of four NAND gates G1 to G4. The NAND gate G1 outputs the result of the NAND operation between the latch signal and the input signal. The NAND gate G2 outputs the result of the NAND operation between the input signal and the output signal of the NAND gate G4. The NAND gate G3 outputs the result of the NAND operation between the output signal of the NAND gate G4 and the inverted signal of the latch signal. The NAND gate G4 outputs the result of the NAND operation of the output signals of the NAND gates G1 to G3 as a holding signal of the latch 20.

FIG. 9B is a circuit diagram illustrating a second specific example of the latch 20 of FIG. 7. The latch 20 in FIG. 9B includes an NMOS transistor 21 and a capacitor 22. A latch signal is input to the gate of the NMOS transistor 21, an input signal is input to the source of the NMOS transistor 21, and a holding signal of the latch 20 is output from the drain of the NMOS transistor 21. The capacitor 22 is connected between the drain of the NMOS transistor 21 and the ground node.

In this way, in the imaging device 100 according to the first embodiment, the ADC 105a determines whether the illuminance is equal to or higher than the reference level at the time of starting imaging, and the determination signal is sent to the pixel unit PX via the vertical signal line VSL. In the pixel unit PX, after the determination signal is held in the latch 20, each control signal is selected by the control signal selection circuit 19 based on the determination signal to operate each transistor in the pixel unit PX. As a result, if the illuminance is equal to or higher than the reference level, the SP2H reset level, the SP2H data (pixel signal) level, the SP2L data (pixel signal) level, and the SP2L reset level can be sequentially generated during one horizontal line period. Further, if the illuminance is less than the reference level, the SP1L reset level, the SP1H reset level, the SP1H data (pixel signal) level, and the SP1L data (pixel signal) level can be sequentially generated during one horizontal line period.

In the first embodiment, since AD conversion processing is performed a minimum number of times depending on the illuminance, the frame rate can be increased and power consumption can also be reduced.

Further, in the first embodiment, since the illuminance determination signal is transmitted to the pixel unit PX via the vertical signal line VSL, there is no need to separately provide a wiring for the determination signal, and the number of wirings can be reduced. In order to transmit the determination signal via the vertical signal line VSL, the function of the vertical signal line VSL must be temporarily switched. Therefore, by operating the first to fifth switching circuits 12 to 16 in conjunction with each other, the determination signal is transmitted through the vertical signal line VSL only for a predetermined period.

In this way, since the determination signal on the vertical signal line VSL exists only for a predetermined period, the determination signal is held in the latch 20 in the pixel unit PX. In this way, the control signal selection circuit 19 in the pixel unit PX can switch control signals based on the held determination signal even if the determination signal on the vertical signal line VSL no longer exists.

### Second Embodiment

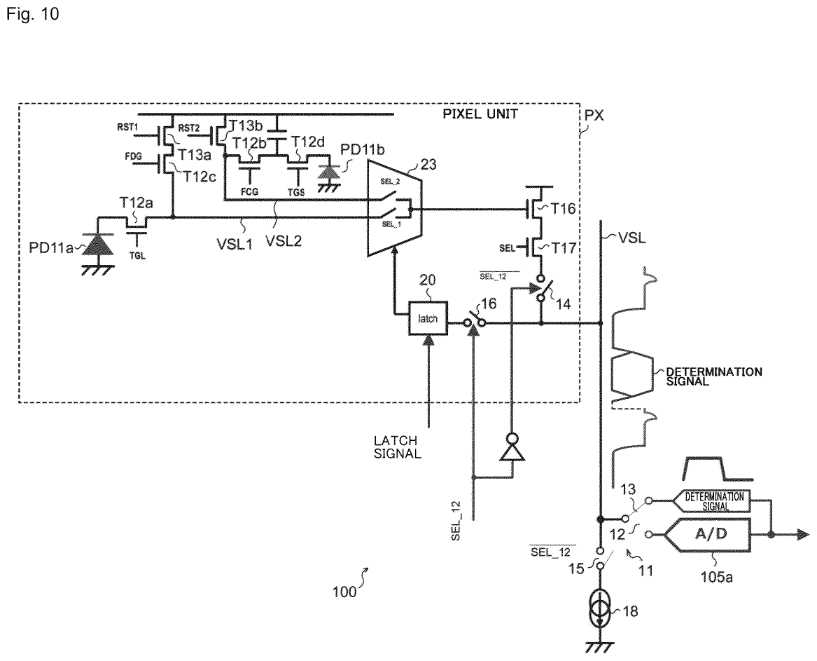

FIG. 10 is a circuit diagram of the main parts of an imaging device 100 according to the second embodiment. The pixel unit PX in the imaging device 100 in FIG. 10 has a different configuration from the pixel unit PX in FIG. 6. On the other hand, the internal configuration of the ADC 105a in FIG. 10 is the same as that of the ADC 105a in FIG. 6. Hereinafter, differences from the imaging device 100 of FIG. 6 will be mainly described.

The pixel unit PX in FIG. 10 has a VSL selector 23 instead of the control signal selection circuit 19 in the pixel unit PX in FIG. 6. The VSL selector 23 selects either the first signal line VSL1 or the second signal line VSL2 based on the determination signal held in the latch 20. The pixel signal selected by the VSL selector 23 is input to the gate of the amplification transistor T16. The first signal line VSL1 transmits a first pixel signal corresponding to the charge photoelectrically converted by the first photoelectric conversion portion PD11a having a large light-receiving area. The second signal line VSL2 transmits a second pixel signal corresponding to the charge photoelectrically converted by the second photoelectric conversion portion PD11b having a small light-receiving area.

The pixel unit PX in FIG. 10 is provided with a third switching circuit 14 and a fifth switching circuit 16, similar to the pixel unit PX in FIG. 6. The third switching circuit 14 switches whether to output the pixel signal generated in the pixel unit PX to the vertical signal line VSL. The fifth switching circuit 16 switches whether to input the determination signal output from the ADC 105a via the vertical signal line VSL to the latch 20. The first to fifth switching circuits 12 to 16 perform switching operations in conjunction with each other.

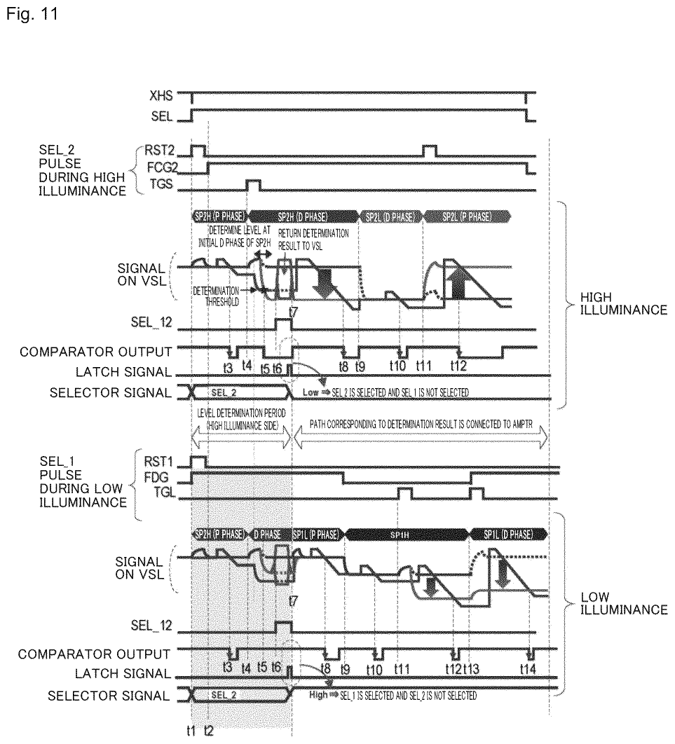

FIG. 11 is a timing diagram of the imaging device 100 of FIG. 10, and is similar to FIG. 8. When starting imaging, the illuminance is determined based on the second pixel signal corresponding to the charge photoelectrically converted by the second photoelectric conversion portion PD11b having a small light-receiving area. Therefore, at the time of starting imaging, the VSL selector 23 selects the second signal line VSL2.

When it is determined that the illuminance is equal to or higher than the reference level, the imaging device 100 operates according to the timing illustrated in the upper half of FIG. 11. In this case, with the VSL selector 23 continuously selecting the second pixel signal on the second signal line VSL2, AD conversions in SP2H (reset period), SP2H (data acquisition period), SP2L (data acquisition period), and SP2L (reset period) are performed sequentially within one horizontal line period.

On the other hand, if the illuminance is determined to be less than the reference level, the imaging device 100 operates according to the timing illustrated in the lower half of FIG. 11. In this case, after time t7, the VSL selector 23 switches to select the first signal line VSL1. Then, during one horizontal line period, AD conversions in SP1L (reset period), SP1H (reset period, data acquisition period), and SP1L (data acquisition period) are performed sequentially.

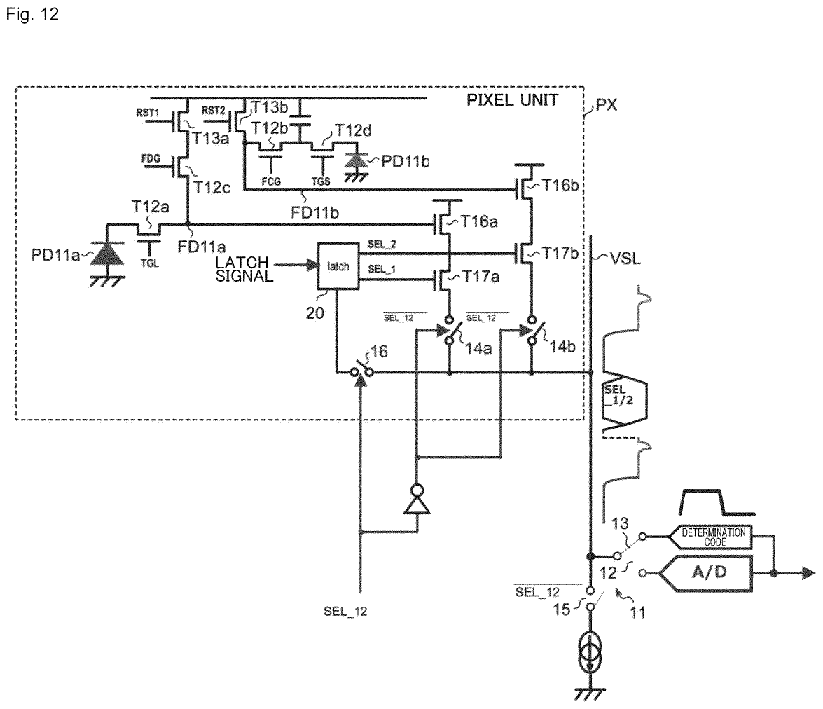

FIG. 12 is a circuit diagram of main parts of a first modification of the imaging device 100 of FIG. 10. The imaging device 100 in FIG. 12 includes, instead of the VSL selector 23 of FIG. 10, a first amplification transistor T16a and a first selection transistor T17a for the first pixel signal, a second amplification transistor T16b and a second selection transistor T17b for the second pixel signal, a 3a-th switching circuit 14a that switches whether to output the first pixel signal to the vertical signal line VSL, and a 3b-th switching circuit 14b that switches whether to output the second pixel signal to the vertical signal line VSL.

The gate of the first amplification transistor T16a is connected to the first floating diffusion region FD15a. The gate of the second amplification transistor T16b is connected to the second floating diffusion region FD15b. The gate of the first selection transistor T17a and the gate of the second selection transistor T17b are connected to the latch 20. The 3a-th switching circuit 14a is connected between the source of the first selection transistor T17a and the vertical signal line VSL. The 3b-th switching circuit 14b is connected between the source of the second selection transistor T17b and the vertical signal line VSL.

The latch 20 holds the determination signal from the ADC 105a. The latch 20 turns on the second selection transistor T17b and turns off the first selection transistor T17a when the illuminance is equal to or higher than the reference level, and turns on the first selection transistor T17a and turns off the second selection transistor T17b when the illuminance is less than the reference level.

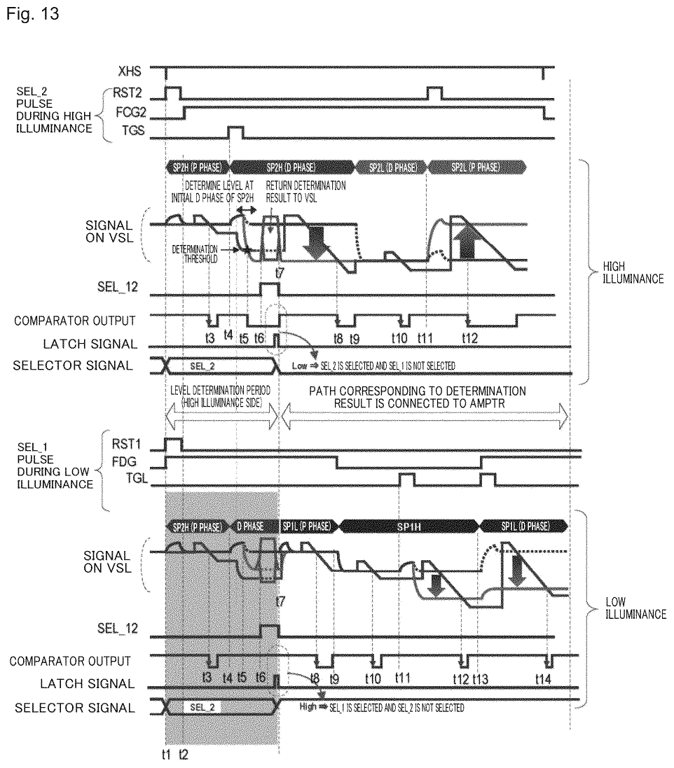

FIG. 13 is a timing diagram of the imaging device 100 of FIG. 12. The timing diagram of FIG. 13 is similar to that of FIG. 11. At time t5, a determination signal indicating whether the illuminance is equal to or higher than the reference level is output to the vertical signal line VSL. After this determination signal is held in the latch 20, either the first selection transistor T17a or the second selection transistor T17b is turned on, and AD conversion processing is performed a plurality of times within one frame period.

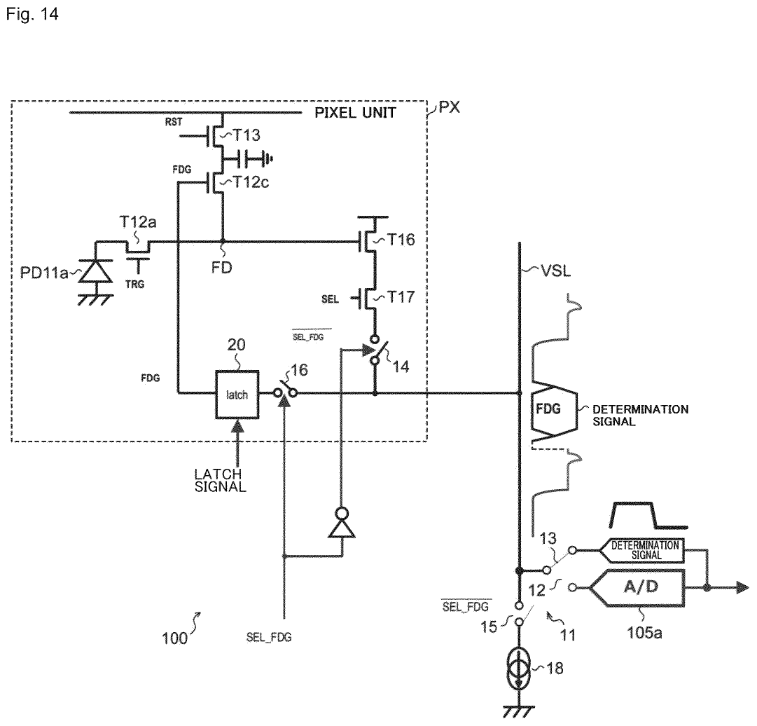

FIG. 14 is a circuit diagram of main parts of a second modification of the imaging device 100 of FIG. 10. The imaging device 100 in FIG. 14 has a simplified internal configuration of the pixel unit PX. Although the pixel unit PX in FIG. 14 has a function of switching charge-voltage conversion efficiency, it does not have a function of changing sensitivity. The pixel unit PX is provided with only one photoelectric conversion portion PD11. The latch 20 holding the determination signal controls the turning on or off of the conversion efficiency switching transistor T12c. In addition, the pixel unit PX includes a transfer transistor T12a, a reset transistor T13, an amplification transistor T16, a selection transistor T17, a third switching circuit 14, and a fifth switching circuit 16.

At the time of starting imaging, the conversion efficiency switching transistor T12c is turned off, increasing the conversion efficiency. When the ADC 105a determines that the illuminance is equal to or higher than the reference level, the latch 20 turns on the conversion efficiency switching transistor T12c to lower the conversion efficiency. On the other hand, when it is determined that the illuminance is less than the reference level, the latch 20 keeps the conversion efficiency switching transistor T12c off, thereby setting the conversion efficiency to a high state.

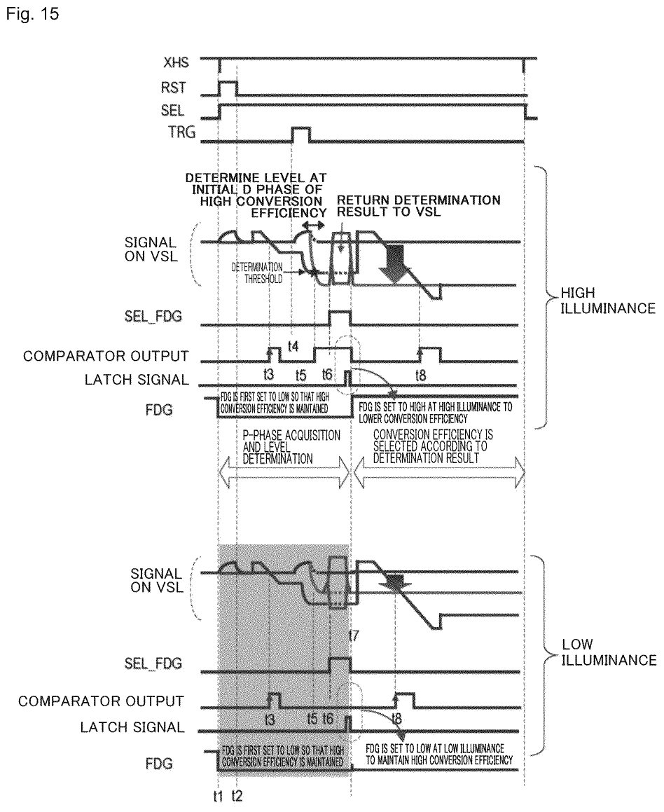

FIG. 15 is a timing diagram of the imaging device 100 of FIG. 14. As described above, at time t1, the conversion efficiency switching transistor T12c is turned off, increasing the conversion efficiency. At time t1, the reset transistor is turned on, and the charges in the floating diffusion region FD are discharged. Thereafter, when the pixel signal crosses the reference signal at time t3, the output signal of the comparator 121 transitions to a high level. Note that the output signal of the comparator 121 may transition to a low level when the pixel signal crosses the reference signal. The counter 122 counts the time until the pixel signal crosses the reference signal, and the count value represents the reset level.

Thereafter, when the transfer transistor T12a is turned on at time t4, the charge photoelectrically converted by the photoelectric conversion portion PD11 is transferred to the floating diffusion region FD via the transfer transistor T12a. When the pixel signal crosses the reference signal at time t5, the output signal of the comparator 121 transitions to a high level. The counter 122 counts the time until the pixel signal crosses the reference signal, and the count value represents the data (pixel signal) level.

At time t5, the ADC 105a determines whether the illuminance is equal to or higher than a predetermined reference level, and outputs a determination signal indicating the determination result to the vertical signal line VSL. The timing in the upper half of FIG. 15 indicates the case where the illuminance is determined to be equal to or higher than the reference level. In this case, the latch 20 holding the determination signal keeps the conversion efficiency switching transistor T12c off.

The timing in the lower half of FIG. 15 illustrates the case where the illuminance is determined to be less than the reference level. In this case, the latch 20 holding the determination signal turns on the conversion efficiency switching transistor T12c.

Note that the internal configuration of the latch 20 in the pixel unit PX in FIGS. 10, 12, and 14 may be the same as or different from that in FIG. 9A or 9B.

In this manner, in the second embodiment, a signal path through which the first photoelectric conversion portion PD11a generates the first pixel signal and a signal path through which the second photoelectric conversion portion PD11b generates the second pixel signal are provided separately, and either the first pixel signal or the second pixel signal is selected and output to the vertical signal line VSL. In this way, the control signal selection circuit 19 in FIG. 6 becomes unnecessary.

Although the imaging device 100 in FIG. 14 has the function of switching conversion efficiency, by omitting the function of switching sensitivity, the internal configuration of the pixel unit PX can be simplified, and a plurality of AD conversion processes can be performed while switching the conversion efficiency based on the illuminance determination signal from the ADC 105a.

### Third Embodiment

In the first and second embodiments, although an example has been illustrated in which the illuminance determination signal is transmitted to the pixel unit PX via the vertical signal line VSL, a separate transmission line L1 for transmitting the determination signal may be provided.

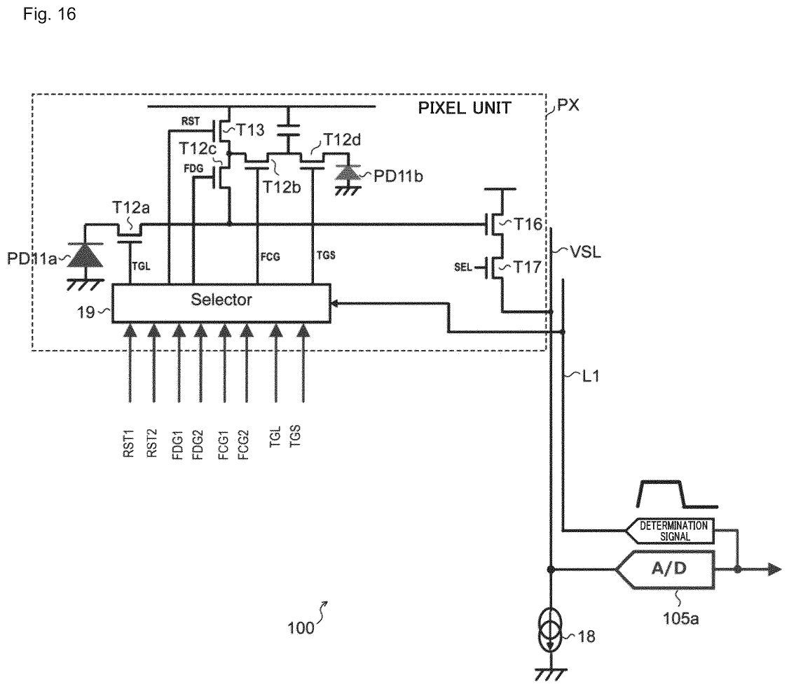

FIG. 16 is a circuit diagram of the main parts of the imaging device 100 according to the third embodiment. The pixel unit PX in the imaging device 100 in FIG. 16 is similar to the pixel unit PX in FIG. 6, but the latch 20, the third switching circuit 14, and the fifth switching circuit 16 in the pixel unit PX in FIG. 6 are omitted.

The imaging device 100 in FIG. 16 includes a transmission line L1 that transmits an illuminance determination signal, separately from the vertical signal line VSL. When the ADC 105a determines the illuminance, the ADC 105a transmits a determination signal to the transmission line L1. Specifically, the potential of the transmission line L1 changes according to the determination signal, and the changed potential is maintained.

The pixel unit PX can determine the illuminance determination result based on the potential of the transmission line L1. Since the potential of the transmission line L1 is maintained until the next illuminance determination is performed, there is no need to provide the latch 20 within the pixel unit PX. Further, since there is no need to switch whether to transmit the determination signal or the pixel signal through the vertical signal line VSL, it is not necessary to provide the third switching circuit 14 and the fifth switching circuit 16 in the pixel unit PX.

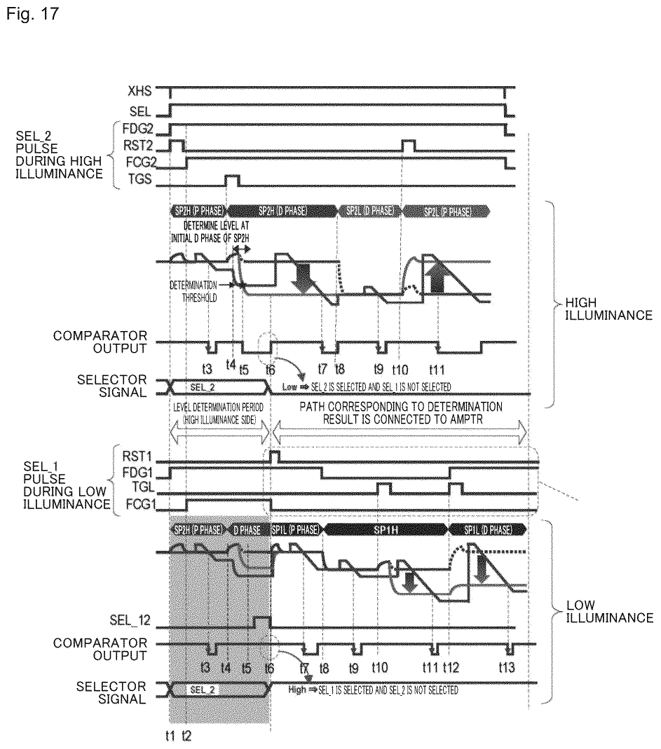

FIG. 17 is a timing diagram of the imaging device 100 of FIG. 16. As in the first and second embodiments, first, the illuminance is determined by comparing the pixel signal corresponding to the charge photoelectrically converted by the second photoelectric conversion portion PD11b, which has a small light-receiving area, with the reference signal (from time t1 to t5).

When it is determined that the illuminance is equal to or higher than the reference level, the imaging device 100 operates according to the timing illustrated in the upper half of FIG. 17. In this case, AD conversion processing is performed a plurality of times in the order of SP2H (data acquisition period), SP2L (data acquisition period), and SP2L (reset period).

On the other hand, if the illuminance is determined to be less than the reference level, the imaging device 100 operates according to the timing illustrated in the lower half of FIG. 17. In this case, after time t6, AD conversion processing is performed a plurality of times in the order of SP1L (reset period), SP1H (reset period, data acquisition period), and SP1L (data acquisition period).

More specifically, when the illuminance is equal to or higher than the reference level, the pixel signal crosses the reference signal at time t7, and the output signal of the comparator 121 transitions to a low level. In this way, the counter 122 counts the time until the pixel signal crosses the reference signal. This count value represents the SP2H data (pixel signal) level.

Thereafter, at time t9, the pixel signal crosses the reference signal again, and the output signal of the comparator 121 transitions to a low level. In this way, the counter 122 counts the time until the pixel signal crosses the reference signal. This count value represents the SP2L data (pixel signal) level.

Thereafter, at time t10, the reset transistor is turned on, and the charges in the first floating diffusion region FD15a and the second floating diffusion region FD15b are discharged. Thereafter, at time t11, the pixel signal crosses the reference signal and the output signal of the comparator 121 transitions to a low level. In this way, the counter 122 counts the time until the pixel signal crosses the reference signal. This count value represents the SP2L reset level.

If the illuminance is less than the reference level, the reset transistor is turned on at time t6, and the charges in the first floating diffusion region FD15a and the second floating diffusion region FD15b are discharged. Thereafter, at time t7, the pixel signal crosses the reference signal and the output signal of the comparator 121 transitions to a low level. In this way, the counter 122 counts the time until the pixel signal crosses the reference signal. This count value represents the SP1L reset level.

After that, at time t8, the control signal FDG becomes low, the conversion efficiency switching transistor T12c is turned off, and the conversion efficiency becomes high. Thereafter, at time t9, the pixel signal crosses the reference signal and the output signal of the comparator 121 transitions to a low level. In this way, the counter 122 counts the time until the pixel signal crosses the reference signal. This count value represents the SP1H reset level.

Thereafter, at time t10, the transfer transistor T12a is turned on, and the charge photoelectrically converted by the first photoelectric conversion portion PD11a is transferred to the first floating diffusion region FD15a through the transfer transistor T12a. Thereafter, at time t11, the pixel signal crosses the reference signal and the output signal of the comparator 121 transitions to a low level. In this way, the counter 122 counts the time until the pixel signal crosses the reference signal. This count value represents the SP1H data (pixel signal) level.

After that, at time t12, the control signal FDG becomes high, the conversion efficiency switching transistor T12c is turned on, and the conversion efficiency becomes low. Further, at time t12, the transfer transistor T12a is turned on, and the charge photoelectrically converted by the first photoelectric conversion portion PD11a is transferred to the first floating diffusion region FD15a through the transfer transistor T12a. Thereafter, at time t13, the pixel signal crosses the reference signal and the output signal of the comparator 121 transitions to a low level. In this way, the counter 122 counts the time until the pixel signal crosses the reference signal. This count value represents the SP1L data (pixel signal) level.

In this manner, in the third embodiment, since the illuminance determination signal is transmitted through the transmission line L1 separate from the vertical signal line VSL, the latch 20 that holds the determination signal within the pixel unit PX is unnecessary. Furthermore, since it is not necessary to switch the signals transmitted by the vertical signal line VSL, the first to fifth switching circuits 12 to 16 are unnecessary, and the internal configuration of the imaging unit can be simplified.

### Fourth Embodiment

The imaging device 100 according to the fourth embodiment is the imaging device 100 according to the second embodiment in which the transmission line L1 for a determination signal is added.

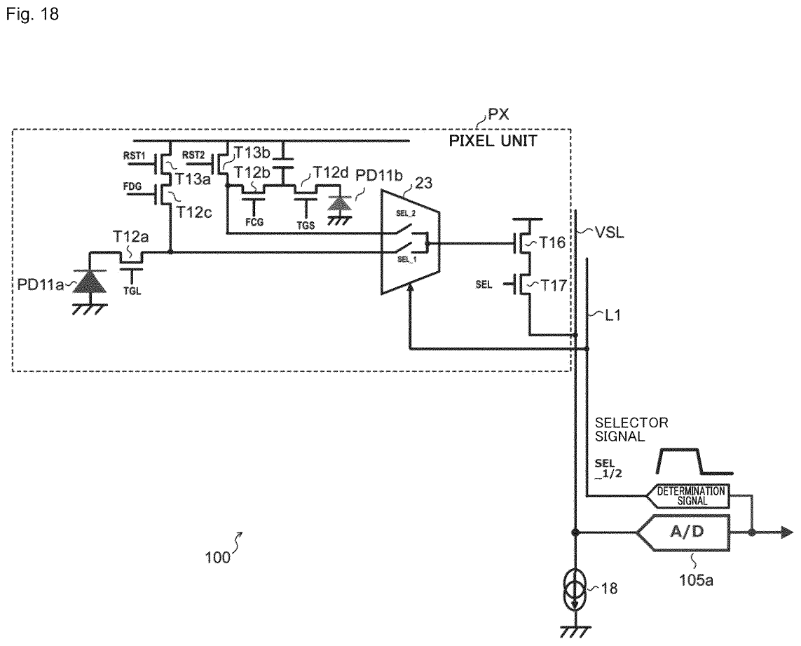

FIG. 18 is a circuit diagram of the main parts of the imaging device 100 according to the fourth embodiment. The imaging device 100 of FIG. 18 omits the first to fifth switching circuits 12 to 16 from the imaging device 100 of FIG. 10, and includes a dedicated transmission line L1 for transmitting the determination signal.

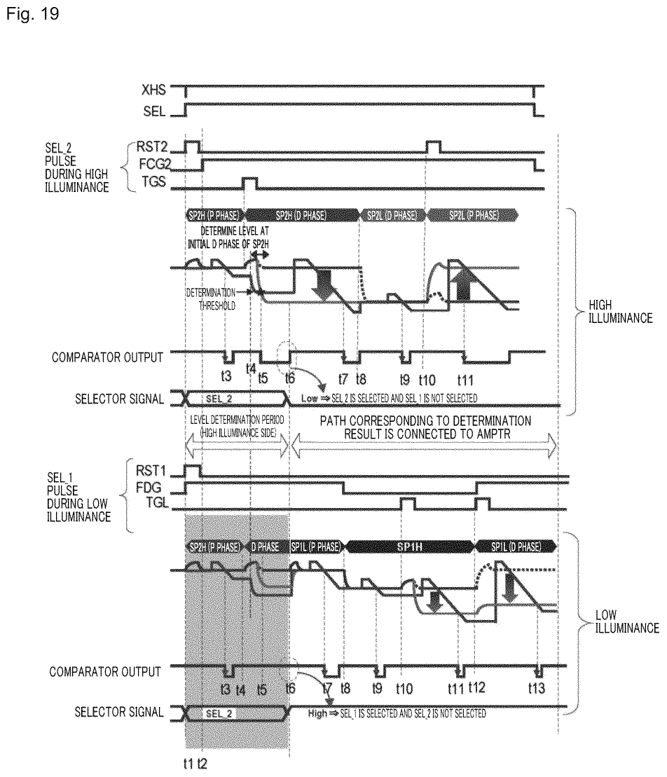

FIG. 19 is a timing diagram of the imaging device 100 of FIG. 18. When it is determined that the illuminance is equal to or higher than the reference level, the imaging device 100 operates according to the timing illustrated in the upper half of FIG. 19. On the other hand, if it is determined that the illuminance is less than the reference level, the imaging device 100 operates according to the timing illustrated in the lower half of FIG. 19.

The timing diagram of FIG. 19 is similar to the timing diagram of FIG. 17. The difference from FIG. 17 is the timing at which the reset transistor T13a is turned on when the illuminance is less than the reference level. In FIG. 17, the reset transistor T13 is turned on at time t6 when the illuminance determination is finished, whereas in FIG. 19, the reset transistor T13a is turned on at time t1 before the illuminance determination is started. In either case, the SP1L reset level can be generated when the pixel signal crosses the reference signal at time t7.

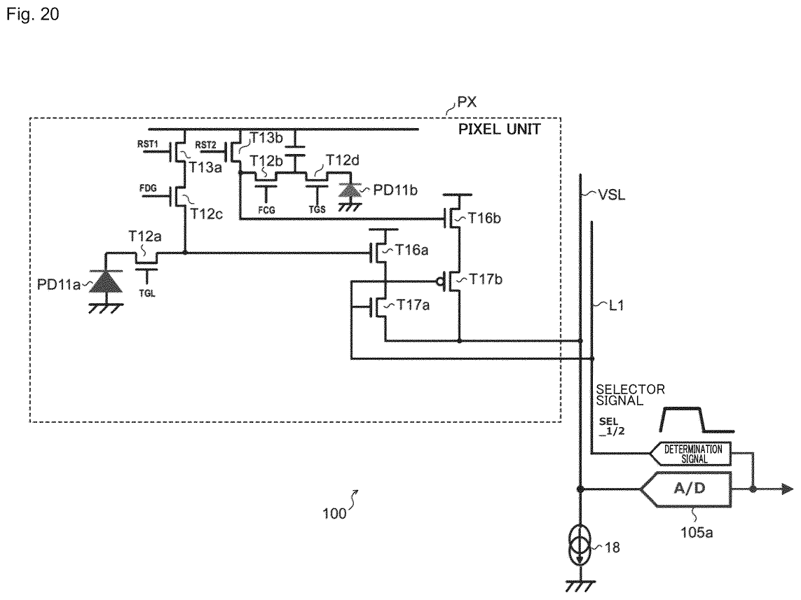

FIG. 20 is a circuit diagram of the main parts of the imaging device 100 according to a modified example of FIG. 18. The imaging device 100 of FIG. 20 omits the first to fifth switching circuits 12 to 16 from the imaging device 100 of FIG. 18, and includes a dedicated transmission line L1 for transmitting the determination signal.

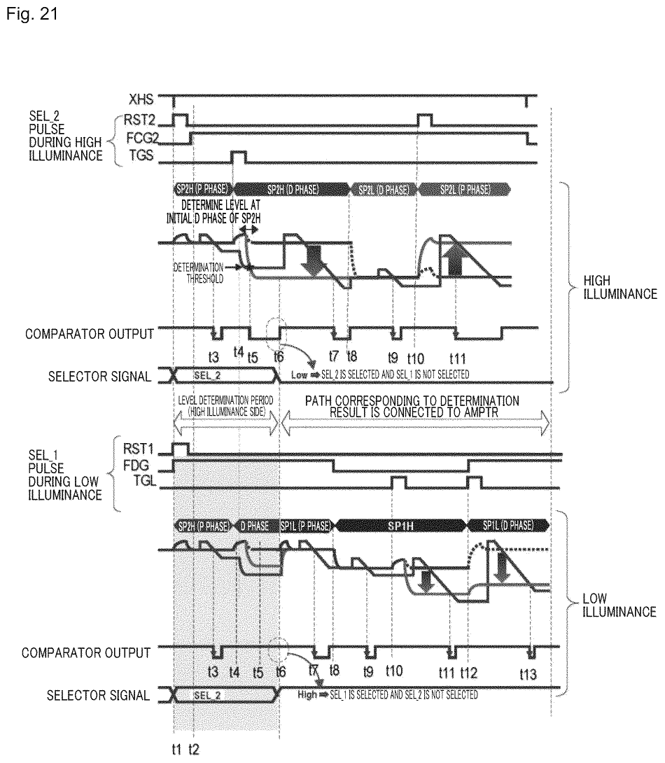

FIG. 21 is a timing diagram of the imaging device 100 of FIG. 20. The timing diagram of FIG. 21 is substantially the same as the timing diagram of FIG. 19. At the time of starting imaging, the illuminance is determined using the second photoelectric conversion portion PD11b with a small light-receiving area. If the illuminance is equal to or higher than the reference level, AD conversion processing is performed a plurality of times in the order of SP2H (reset period), SP2H (data acquisition period), SP2L (data acquisition period), and SP2L (reset period). If the illuminance is less than the reference level, AD conversion processing is performed a plurality of times in the order of SP1L (reset period), SP1H (reset period, data acquisition period), and SP1L (data acquisition period).

In this manner, in the fourth embodiment, since the illuminance determination signal is transmitted through the dedicated transmission line L1 different from the vertical signal line VSL, it is not necessary to provide the latch 20 that holds the determination signal within the pixel unit PX. In addition, since only pixel signals are transmitted to the vertical signal line VSL, the first to fifth switching circuits 12 to 16 are no longer necessary. Therefore, the internal configuration of the imaging unit can be simplified.

### (Cross-Sectional Structure of Imaging Device 100)

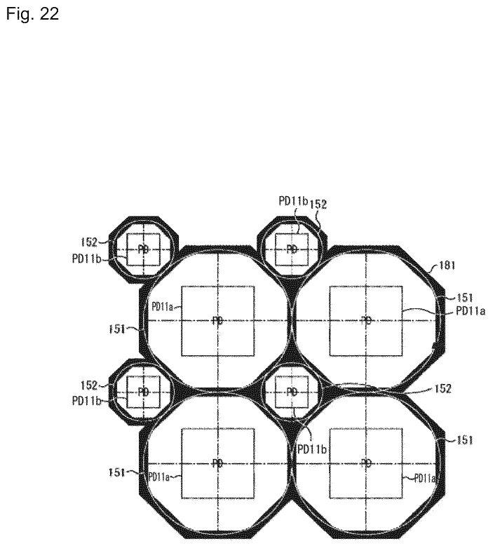

The imaging device 100 according to the first or second embodiment can be realized with one semiconductor chip. FIG. 22 is a planar layout diagram of the light incidence surface side of the imaging device 100 according to the first and second embodiments. The semiconductor chip illustrated in FIG. 22 includes roughly three semiconductor regions (hereinafter referred to as first to third semiconductor regions). The first to third semiconductor regions may be stacked in order, and each semiconductor region may be formed of a plurality of semiconductor layers.

In the first semiconductor region on the light incidence surface side, a first photoelectric conversion portion PD11a with a large light-receiving area and a second photoelectric conversion portion PD11b with a small light-receiving area are arranged for each pixel PX. A portion of the readout circuit may be placed in the first semiconductor region.

At least a part of the readout circuit (for example, an amplification transistor, a selection transistor, or the like) of each pixel PX is arranged in the second semiconductor region. The ADC group 105 and the like are arranged in the third semiconductor region.

The first semiconductor region and the second semiconductor region are stacked, for example, on a first substrate. The third semiconductor region is formed, for example, on a second substrate. The first substrate and the second substrate are bonded by Cu—Cu connections, vias, bumps, or the like.

### (Planar Layout of Imaging Device 100)

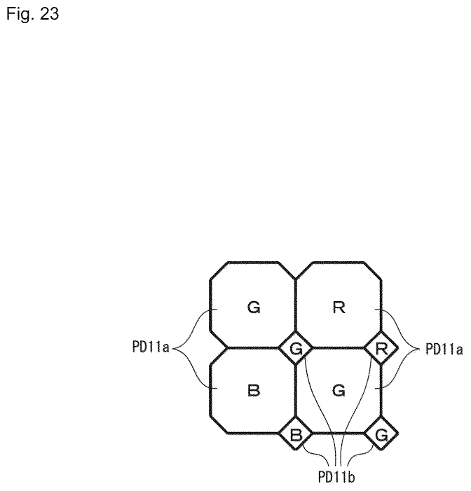

FIG. 23 is a planar layout diagram according to a modified example of FIG. 22. As illustrated in FIG. 23, a first on-chip lens 151 is arranged on the rectangular first photoelectric conversion portion PD11a. Further, an inter-pixel light-shielding portion 181 is arranged around the first photoelectric conversion portion PD11a. The outer shape of the inter-pixel light-shielding portion 181 is octagonal, and a gap is created between adjacent inter-pixel light-shielding portions. The rectangular second photoelectric conversion portion PD11b is arranged in this gap. A second on-chip lens 152 is arranged above the second photoelectric conversion portion PD11b.

FIG. 23 is an example of a planar layout, and the layout is not limited to this. FIG. 17 is a planar layout diagram according to a modified example. In FIG. 23, the shape of the inter-pixel light-shielding portion is close to a regular octagon, whereas in FIG. 17, the four corners of the rectangle are cut to form an octagon. Further, the inter-pixel light-shielding portion of the second photoelectric conversion portion PD11b is not octagonal but square.

### <Application to Mobile Object>

The technology of the present disclosure (the present technology) can be applied to various products. For example, the technique according to the present disclosure may be realized as a device mounted on any type of mobile object such as an automobile, an electric automobile, a hybrid electric automobile, a motorcycle, a bicycle, a personal mobility device, an airplane, a drone, a ship, a robot, or the like.

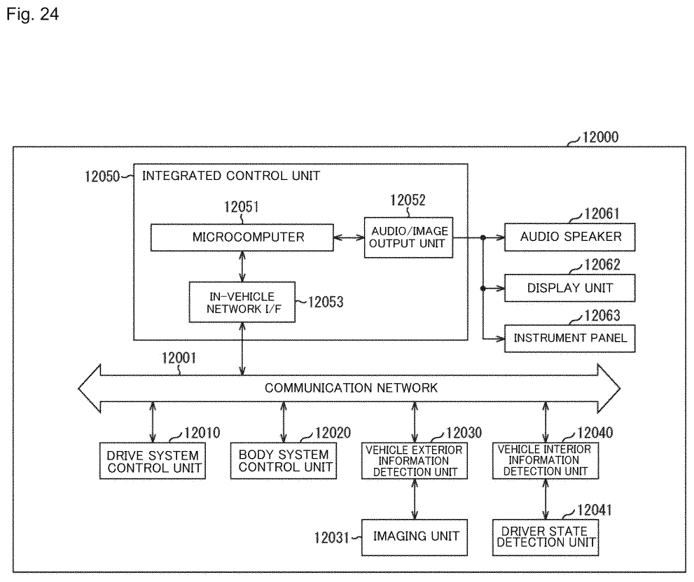

FIG. 24 is a block diagram illustrating a schematic configuration example of a vehicle control system that is an example of a mobile object control system to which the technology according to the present disclosure can be applied.

A vehicle control system 12000 includes a plurality of electronic control units connected to each other over a communication network 12001. In the example illustrated in FIG. 24, the vehicle control system 12000 includes a drive system control unit 12010, a body system control unit 12020, a vehicle exterior information detection unit 12030, a vehicle interior information detection unit 12040, and an integrated control unit 12050. A microcomputer 12051, an audio/image output unit 12052, and an in-vehicle network interface (I/F) 12053 are illustrated as the functional configuration of the integrated control unit 12050.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal corresponding to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate control target values for the driving force generation device, the steering mechanism, or the braking device based on the information on the interior and exterior of the vehicle obtained by the vehicle exterior information detection unit 12030 or the vehicle interior information detection unit 12040, and output control commands to the drive system control unit 12010. For example, the microcomputer 12051 can perform coordinated control for the purpose of implementing functions of an advanced driver assistance system (ADAS) including vehicle collision avoidance, impact mitigation, following traveling based on an inter-vehicle distance, constant vehicle speed driving, vehicle collision warnings, and lane departure warning.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12030 based on the information outside the vehicle acquired by the vehicle exterior information detection unit 12030. For example, the microcomputer 12051 can perform coordinated control for the purpose of antiglare such as switching a high beam to a low beam by controlling a headlamp according to a position of a preceding vehicle or an oncoming vehicle detected by the vehicle exterior information detection unit 12030.

The audio/image output unit 12052 transmits an output signal of at least one of sound and an image to an output device capable of visually or audibly notifying a passenger or the outside of the vehicle of information. In the example illustrated in FIG. 24, as such an output device, an audio speaker 12061, a display unit 12062 and an instrument panel 12063 are illustrated. The display unit 12062 may include at least one of an on-board display and a head-up display, for example.

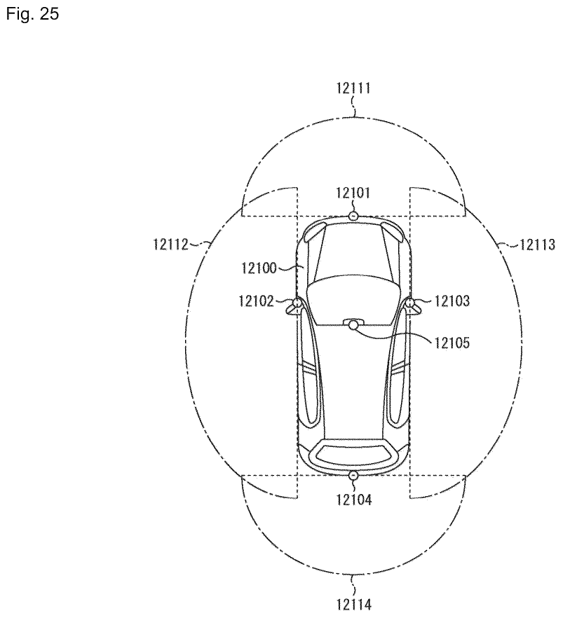

FIG. 25 is a diagram illustrating an example of an installation position of the imaging unit 12031.

In FIG. 25, the imaging unit 12031 includes imaging units 12101, 12102, 12103, 12104, and 12105.

The imaging units 12101, 12102, 12103, 12104, and 12105 are provided at, for example, positions of a front nose, side mirrors, a rear bumper, a back door, an upper portion of a vehicle internal front windshield, and the like of the vehicle 12100. The imaging unit 12101 provided on a front nose and the imaging unit 12105 provided in an upper portion of the vehicle internal front windshield mainly acquire images in front of the vehicle 12100. The imaging units 12102 and 12103 provided in the side mirrors mainly acquire images on the lateral sides of the vehicle 12100. The imaging unit 12104 included in the rear bumper or the back door mainly acquires an image of an area behind the vehicle 12100. The imaging unit 12105 included in the upper portion of the windshield inside the vehicle is mainly used for detection of a preceding vehicle, a pedestrian, an obstacle, a traffic signal, a traffic sign, a lane, or the like.

FIG. 25 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by obtaining a distance to each three-dimensional object in the imaging ranges 12111 to 12114 and temporal change in the distance (a relative speed with respect to the vehicle 12100) based on distance information obtained from the imaging units 12101 to 12104. The microcomputer 12051 can also set a following distance to the preceding vehicle to be maintained in advance and perform automatic brake control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a square contour line for emphasis is superimposed and displayed with the recognized pedestrian. In addition, the audio/image output unit 12052 may control the display unit 12062 so that an icon indicating a pedestrian or the like is displayed at a desired position.

An example of the vehicle control system to which the technology according to the present disclosure can be applied has been described above. The technique according to the present disclosure is applicable to the imaging unit 12031 or the like among the above-described configurations. Specifically, the imaging device 100 of the present disclosure is applicable to the imaging unit 12031. By applying the technique according to the present disclosure to the imaging unit 12031, an image can be more clearly captured, thereby reducing driver fatigue.

The present technique can also take on the following configurations.

(1) An imaging device including: a pixel unit that outputs a photoelectrically converted pixel signal to a signal line;
an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein
the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and the conversion efficiency adjustment circuit adjusts the conversion efficiency based on the determination signal held in the holding circuit.

(2) The imaging device according to (1), wherein the switching circuit switches whether to output a pixel signal from the pixel unit to the signal line, whether to connect a current source to the signal line, whether to input the pixel signal on the signal line to the analog-to-digital converter, whether to supply the determination signal of the illuminance from the analog-to-digital converter to the signal line, and whether to input the determination signal on the signal line to the holding circuit in conjunction with each other.

(3) The imaging device according to (2), wherein after the holding circuit holds the determination signal, a pixel signal from the pixel unit is output to the signal line.

(4) The imaging device according to any one of (1) to (3), further including: a plurality of the pixel units arranged in a first direction and a second direction, wherein
the pixel signals output from two or more pixel units arranged in the second direction are output to a common signal line, and
the signal line and the analog-to-digital converter are arranged for each pixel column made up of two or more pixel units arranged in the second direction.

(5) The imaging device according to any one of (1) to (4), wherein the pixel unit includes a second photoelectric conversion portion having a smaller light-receiving area than the first photoelectric conversion portion, and
the pixel unit outputs a plurality of pixel signals with a combination of a plurality of sensitivities and a plurality of conversion efficiencies by controlling the first photoelectric conversion portion, the second photoelectric conversion portion, and the conversion efficiency adjustment circuit.

(6) The imaging device according to (5), wherein the pixel unit includes a control signal selection circuit that selects a first control signal for adjusting the conversion efficiency and a second control signal for selecting the first photoelectric conversion portion or the second photoelectric conversion portion based on the determination signal held in the holding circuit, and
the pixel unit outputs, to the signal line, the pixel signal which has been photoelectrically converted by the first photoelectric conversion portion or the second photoelectric conversion portion selected based on the second control signal, and of which the conversion efficiency is adjusted based on the first control signal.

(7) The imaging device according to (6), wherein the pixel unit includes a second readout circuit that generates a pixel signal corresponding to the charge photoelectrically converted by the second photoelectric conversion portion, and the control signal selection circuit selects a control signal for the first readout circuit and a control signal for the second readout circuit based on the determination signal held in the holding circuit.

(8) The imaging device according to (5), wherein the pixel unit includes a pixel signal selector that selects either a pixel signal corresponding to the charge photoelectrically converted by the first photoelectric conversion portion and a pixel signal corresponding to the charge photoelectrically converted by the second photoelectric conversion portion based on the determination signal held in the holding circuit and selects the selected pixel signal to the signal line.

(9) The imaging device according to (5), wherein the pixel unit includes a second readout circuit that generates a pixel signal corresponding to the charge photoelectrically converted by the second photoelectric conversion portion, the first readout circuit switches whether to output a pixel signal corresponding to the charge photoelectrically converted by the first photoelectric conversion portion to the signal line based on the determination signal held in the holding circuit, and the second readout circuit switches whether to output a pixel signal corresponding to the charge photoelectrically converted by the second photoelectric conversion portion to the signal line based on the determination signal held in the holding circuit.

(10) The imaging device according to any one of (5) to (9), wherein the analog-to-digital converter includes:
a comparator that compares the pixel signal on the signal line with a reference signal; and
a counter that performs a counting operation until the comparator detects a match between the pixel signal and the reference signal,
the analog-to-digital converter generates a digital pixel signal corresponding to the pixel signal on the signal line based on a count value of the counter, and the comparator generates the determination signal of the illuminance by comparing the pixel signal on the signal line with the reference signal.

(11) The imaging device according to (10), wherein the comparator generates the determination signal indicating whether the illuminance at the time of starting imaging is equal to or higher than a predetermined reference level by comparing the pixel signal on the signal line and the reference signal.

(12) The imaging device according to (10) or (11), further including: a first floating diffusion region that accumulates the charge photoelectrically converted by the first photoelectric conversion portion; and
a second floating diffusion region that accumulates the charge photoelectrically converted by the second photoelectric conversion portion, wherein
the analog-to-digital converter determines the illuminance based on a comparison result from the comparator comparing the pixel signal corresponding to the charge photoelectrically converted by the second photoelectric conversion portion and accumulated in the second floating diffusion region with the reference signal.

(13) The imaging device according to (12), wherein when starting imaging, the comparator performs a first comparison process of comparing the pixel signal corresponding to a potential of the second floating diffusion region in a state in which the charges in the second floating diffusion region are discharged with the reference signal and then performs a second comparison process of comparing the pixel signal corresponding to the charge photoelectrically converted by the second photoelectric conversion portion and accumulated in the second floating diffusion region with the reference signal, and
the analog-digital converter determines the illuminance based on the result of the second comparison process.

(14) The imaging device according to (13), wherein the comparator determines whether the illuminance at the time of starting imaging is equal to or higher than the reference level in the second comparison process, and
the pixel unit outputs a pixel signal corresponding to the charge photoelectrically converted by the second photoelectric conversion portion to the signal line when the illuminance is equal to or higher than the reference level, and outputs a pixel signal corresponding to the charge photoelectrically converted by the first photoelectric conversion portion to the signal line when the illuminance is less than the reference level.

(15) The imaging device according to (14), wherein when the illuminance is determined to be equal to or higher than the reference level in the second comparison process, the comparator performs a third comparison process of comparing the pixel signal corresponding to the charge photoelectrically converted by the second photoelectric conversion portion and accumulated in the second floating diffusion region with the reference signal and then performs a fourth comparison process of comparing the pixel signal corresponding to the potential of the second floating diffusion region in a state in which the charges in the second floating diffusion region are discharged with the reference signal.

(16) The imaging device according to (14) or (15), wherein when the illuminance is determined to be less than the reference level in the second comparison process, the comparator performs a fifth comparison process of comparing the pixel signal corresponding to the potential of the first floating diffusion region in a state where the charges of the first floating diffusion region are discharged with the reference signal, then performs a sixth comparison process of comparing the pixel signal corresponding to the potential of the first floating diffusion region in a state where a charge-potential conversion efficiency is higher than in the fifth comparison process and the charges of the first floating diffusion region are discharged with the reference signal, then performs a seventh comparison process of comparing the pixel signal corresponding to the charge photoelectrically converted by the first photoelectric conversion portion with the same charge-potential conversion efficiency as in the sixth comparison process with the reference signal, and then performs an eighth comparison process of comparing the pixel signal corresponding to the charge photoelectrically converted by the first photoelectric conversion portion with the same charge-potential conversion efficiency as in the fifth comparison process with the reference signal.

(17) An electronic apparatus including: an imaging device that outputs a digital pixel signal corresponding to an imaged pixel signal; and
a signal processing unit that performs signal processing based on the digital pixel signal, wherein
the imaging device includes:
a pixel unit that outputs a photoelectrically converted pixel signal to a signal line;
an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein
the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and the conversion efficiency adjustment circuit adjusts the conversion efficiency based on the determination signal held in the holding circuit.

(18) An imaging device including: a pixel unit that outputs a photoelectrically converted pixel signal to a signal line;
a first switching circuit that switches whether to connect a current source to the signal line;
an analog-to-digital converter that converts the pixel signal on the signal line from analog to digital and determines illuminance based on the pixel signal; and
a determination signal generation circuit that outputs a determination signal of the illuminance to a wiring provided separately from the signal line in a state where the current source is cut off from the signal line by the switching circuit, wherein
the pixel unit includes:
a first photoelectric conversion portion;
a conversion efficiency adjustment circuit that varies the conversion efficiency when converting the charge photoelectrically converted by the first photoelectric conversion portion into voltage; and
a first readout circuit that outputs a pixel signal corresponding to the charge photoelectrically converted by the first photoelectric conversion portion to a signal line, and
the conversion efficiency adjustment circuit adjusts the conversion efficiency based on the determination signal on the wiring.

(19) The imaging device according to (18), wherein the pixel unit has a second photoelectric conversion portion having a smaller light receiving area than the first photoelectric conversion portion, and the pixel unit adjusts the conversion efficiency based on the determination signal on the wiring, and outputs the pixel signal corresponding to the charge photoelectrically converted by the first photoelectric conversion portion or the second photoelectric conversion portion to the signal line.

(20) The imaging device according to (19), wherein the pixel unit includes a control signal selection circuit that selects a first control signal that adjusts the conversion efficiency and a second control signal that selects the first photoelectric conversion portion or the second photoelectric conversion portion based on the determination signal on the wiring.

(21) The imaging device according to (20), wherein the pixel unit outputs, to the signal line, the pixel signal which has been photoelectrically converted by the first photoelectric conversion portion or the second photoelectric conversion portion selected based on the second control signal, and of which the conversion efficiency is adjusted based on the first control signal.

(22) The imaging device according to (20) or (21), wherein the pixel unit includes a second readout circuit that generates a pixel signal corresponding to the charge photoelectrically converted by the second photoelectric conversion portion, and the control signal selection circuit selects a control signal for the first readout circuit and a control signal for the second readout circuit based on the determination signal on the wiring.

(23) The imaging device according to (19), wherein the pixel unit includes a pixel signal selector that selects either a first pixel signal corresponding to the charge photoelectrically converted by the first photoelectric conversion portion or a second pixel signal corresponding to the charge photoelectrically converted by the second photoelectric conversion portion based on the determination signal on the wiring and outputs the selected pixel signal to the signal line.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

11 Switching circuit
12 First switching circuit
13 Second switching circuit
14 Third switching circuit
14a 3a-th switching circuit
14b 3b-th switching circuit
15 Fourth switching circuit
16 Fifth switching circuit
18 Current source
19 Control signal selection circuit
20 Latch,
21 PMOS transistor
22 Capacitor
23 VSL selector
100 Imaging device
101 Pixel array unit
102 Timing control circuit
103 Vertical scanning circuit
104 Charge accumulation portion
105 ADC group
106 Horizontal Transfer scanning circuit
107 Amplifier circuit
108 Signal processing circuit
109 Pixel drive line
111 Horizontal transfer line
114 Reference signal line
121 Comparator
122 Counter
123 Latch circuit
151 First on-chip lens
152 Second on-chip lens
181 Interpixel light-shielding portion
511 Semiconductor chip
512 Semiconductor chip
516 Logic circuit
517 Peripheral circuit

1. An imaging device comprising:
a pixel unit that outputs a photoelectrically converted pixel signal to a signal line;
an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein
the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and
the conversion efficiency adjustment circuit adjusts the conversion efficiency based on the determination signal held in the holding circuit.

2. The imaging device according to claim 1, wherein
the switching circuit switches whether to output a pixel signal from the pixel unit to the signal line, whether to connect a current source to the signal line, whether to input the pixel signal on the signal line to the analog-to-digital converter, whether to supply the determination signal of the illuminance from the analog-to-digital converter to the signal line, and whether to input the determination signal on the signal line to the holding circuit in conjunction with each other.

3. The imaging device according to claim 2, wherein
after the holding circuit holds the determination signal, a pixel signal from the pixel unit is output to the signal line.

4. The imaging device according to claim 1, further comprising:
a plurality of the pixel units arranged in a first direction and a second direction, wherein
the pixel signals output from two or more pixel units arranged in the second direction are output to a common signal line, and
the signal line and the analog-to-digital converter are arranged for each pixel column made up of two or more pixel units arranged in the second direction.

5. The imaging device according to claim 1, wherein
the pixel unit includes a second photoelectric conversion portion having a smaller light-receiving area than the first photoelectric conversion portion, and
the pixel unit outputs a plurality of pixel signals with a combination of a plurality of sensitivities and a plurality of conversion efficiencies by controlling the first photoelectric conversion portion, the second photoelectric conversion portion, and the conversion efficiency adjustment circuit.

6. The imaging device according to claim 5, wherein
the pixel unit includes a control signal selection circuit that selects a first control signal for adjusting the conversion efficiency and a second control signal for selecting the first photoelectric conversion portion or the second photoelectric conversion portion based on the determination signal held in the holding circuit, and
the pixel unit outputs, to the signal line, the pixel signal which has been photoelectrically converted by the first photoelectric conversion portion or the second photoelectric conversion portion selected based on the second control signal, and of which the conversion efficiency is adjusted based on the first control signal.

7. The imaging device according to claim 6, wherein
the pixel unit includes a second readout circuit that generates a pixel signal corresponding to the charge photoelectrically converted by the second photoelectric conversion portion, and
the control signal selection circuit selects a control signal for the first readout circuit and a control signal for the second readout circuit based on the determination signal held in the holding circuit.

8. The imaging device according to claim 5, wherein
the pixel unit includes a pixel signal selector that selects either a pixel signal corresponding to the charge photoelectrically converted by the first photoelectric conversion portion and a pixel signal corresponding to the charge photoelectrically converted by the second photoelectric conversion portion based on the determination signal held in the holding circuit and selects the selected pixel signal to the signal line.

9. The imaging device according to claim 5, wherein
the pixel unit includes a second readout circuit that generates a pixel signal corresponding to the charge photoelectrically converted by the second photoelectric conversion portion,
the first readout circuit switches whether to output a pixel signal corresponding to the charge photoelectrically converted by the first photoelectric conversion portion to the signal line based on the determination signal held in the holding circuit, and the second readout circuit switches whether to output a pixel signal corresponding to the charge photoelectrically converted by the second photoelectric conversion portion to the signal line based on the determination signal held in the holding circuit.

10. The imaging device according to claim 5, wherein
the analog-to-digital converter includes:
a comparator that compares the pixel signal on the signal line with a reference signal; and
a counter that performs a counting operation until the comparator detects a match between the pixel signal and the reference signal,
the analog-to-digital converter generates a digital pixel signal corresponding to the pixel signal on the signal line based on a count value of the counter, and
the comparator generates the determination signal of the illuminance by comparing the pixel signal on the signal line with the reference signal.

11. The imaging device according to claim 10, wherein
the comparator generates the determination signal indicating whether the illuminance at the time of starting imaging is equal to or higher than a predetermined reference level by comparing the pixel signal on the signal line and the reference signal.

12. The imaging device according to claim 10, further comprising:
a first floating diffusion region that accumulates the charge photoelectrically converted by the first photoelectric conversion portion; and
a second floating diffusion region that accumulates the charge photoelectrically converted by the second photoelectric conversion portion, wherein
the analog-to-digital converter determines the illuminance based on a comparison result from the comparator comparing the pixel signal corresponding to the charge photoelectrically converted by the second photoelectric conversion portion and accumulated in the second floating diffusion region with the reference signal.

13. The imaging device according to claim 12, wherein
when starting imaging, the comparator performs a first comparison process of comparing the pixel signal corresponding to a potential of the second floating diffusion region in a state in which the charges in the second floating diffusion region are discharged with the reference signal and then performs a second comparison process of comparing the pixel signal corresponding to the charge photoelectrically converted by the second photoelectric conversion portion and accumulated in the second floating diffusion region with the reference signal, and the analog-digital converter determines the illuminance based on the result of the second comparison process.

14. The imaging device according to claim 13, wherein
the comparator determines whether the illuminance at the time of starting imaging is equal to or higher than the reference level in the second comparison process, and the pixel unit outputs a pixel signal corresponding to the charge photoelectrically converted by the second photoelectric conversion portion to the signal line when the illuminance is equal to or higher than the reference level, and outputs a pixel signal corresponding to the charge photoelectrically converted by the first photoelectric conversion portion to the signal line when the illuminance is less than the reference level.

15. The imaging device according to claim 14, wherein
when the illuminance is determined to be equal to or higher than the reference level in the second comparison process, the comparator performs a third comparison process of comparing the pixel signal corresponding to the charge photoelectrically converted by the second photoelectric conversion portion and accumulated in the second floating diffusion region with the reference signal and then performs a fourth comparison process of comparing the pixel signal corresponding to the potential of the second floating diffusion region in a state in which the charges in the second floating diffusion region are discharged with the reference signal.

16. The imaging device according to claim 14, wherein
when the illuminance is determined to be less than the reference level in the second comparison process, the comparator performs a fifth comparison process of comparing the pixel signal corresponding to the potential of the first floating diffusion region in a state where the charges of the first floating diffusion region are discharged with the reference signal, then performs a sixth comparison process of comparing the pixel signal corresponding to the potential of the first floating diffusion region in a state where a charge-potential conversion efficiency is higher than in the fifth comparison process and the charges of the first floating diffusion region are discharged with the reference signal, then performs a seventh comparison process of comparing the pixel signal corresponding to the charge photoelectrically converted by the first photoelectric conversion portion with the same charge-potential conversion efficiency as in the sixth comparison process with the reference signal, and then performs an eighth comparison process of comparing the pixel signal corresponding to the charge photoelectrically converted by the first photoelectric conversion portion with the same charge-potential conversion efficiency as in the fifth comparison process with the reference signal.

17. An electronic apparatus comprising:
an imaging device that outputs a digital pixel signal corresponding to an imaged pixel signal; and
a signal processing unit that performs signal processing based on the digital pixel signal, wherein
the imaging device includes:
a pixel unit that outputs a photoelectrically converted pixel signal to a signal line;
an analog-to-digital converter that converts the pixel signal on the signal line from analog to digital and determines illuminance based on the pixel signal;
a switching circuit that switches whether to input the pixel signal on the signal line to the analog-to-digital converter and whether to output a determination signal of the illuminance determined by the analog-to-digital converter to the signal line in conjunction with each other, wherein
the pixel unit includes:
a first photoelectric conversion portion;
a conversion efficiency adjustment circuit that switches conversion efficiency when converting the charge photoelectrically converted by the first photoelectric conversion portion into a voltage;
a first readout circuit that outputs a pixel signal corresponding to the charge photoelectrically converted by the first photoelectric conversion portion to a signal line; and
a holding circuit that holds the determination signal, and
the conversion efficiency adjustment circuit adjusts the conversion efficiency based on the determination signal held in the holding circuit.
